(19) United States
(12) Patent Application Publication
(10) Pub. No.: US 2025/0225932 A1
(43) Pub. Date: Jul. 10, 2025

(54) DISPLAY DEVICE

(71) Applicant: Samsung Display Co., LTD., Yongin-si (KR)

(72) Inventors: Jae Hyuk CHOI, Yongin-si (KR); Nack Hyeon KEUM, Yongin-si (KR); Kyung Hoon KIM, Yongin-si (KR); Yong Chan KIM, Yongin-si (KR); Eseudeo YUN, Yongin-si (KR)

(21) Appl. No.: 18/811,210

(22) Filed: Aug. 21, 2024

(30) Foreign Application Priority Data
Jan. 29, 2024 (KR) 10-2024-0013113

(51) Int. Cl. G09G 3/3233; G09G 3/32; G09G 3/3291

(52) U.S. Cl. CPC G09G 3/3233; G09G 3/32; G09G 3/3291; G09G 2310/0275; G09G 2310/08

(57) ABSTRACT

A display device having high integration density and high resolution includes a pixel circuit and a light-emitting element connected between a second node of the pixel circuit and a common voltage line, wherein the pixel circuit includes a first transistor, which is connected between a driving voltage line and the second node, where the first transistor includes a gate electrode, which is connected to a first node, and a counter gate electrode, which is connected to an emission line.

This application claims priority to Korean Patent Application No. 10-2024-0013113, filed on Jan. 29, 2024, and all the benefits accruing therefrom under 35 U.S.C. § 119, the content of which in its entirety is herein incorporated by reference.

### BACKGROUND

### 1. Field

The present invention relates to a display device, and more particularly to a display device having a high integration density and a high resolution.

### 2. Description of the Related Art

An organic light emitting display device includes display elements whose luminance varies with the current, such as organic light-emitting diodes (OLEDs).

### SUMMARY

Aspects of the invention provide a display device having a high integration density and a high resolution.

According to an embodiment, a display device includes a pixel circuit and a light-emitting element connected between a second node of the pixel circuit and a common voltage line, wherein the pixel circuit includes a first transistor, which is connected between a driving voltage line and the second node, and where the first transistor includes a gate electrode, which is connected to a first node, and a counter gate electrode, which is connected to an emission line.

In an embodiment, the pixel circuit further includes a second transistor connected between a data line and the first node.

In an embodiment, the pixel circuit further includes a third transistor connected between a reference voltage line and the first node.

In an embodiment, the pixel circuit further includes a fourth transistor connected between the second node and an initialization voltage line.

In an embodiment, the pixel circuit further includes a first capacitor connected between the first and second nodes and a second capacitor connected between the second node and the driving voltage line.

In an embodiment, the pixel circuit further includes a first gate line connected to a gate electrode of the second transistor, a second gate line connected to a gate electrode of the third transistor and a third gate line connected to a gate electrode of the fourth transistor.

In an embodiment, the data line transmits a data voltage, the emission line transmits an emission signal, the first gate line transmits a first gate signal, the second gate line transmits a second gate signal, and the third gate line transmits a third gate signal.

In an embodiment, during a first initialization period, each of the second and third gate signals is at an active level, and each of the first gate signal and the emission signal is at a non-active level.

In an embodiment, during a threshold voltage detection period that follows the first initialization period, each of the second gate signal and the emission signal is at the active level, and each of the first and third gate signals is at the non-active level.

In an embodiment, during a data write period that follows the threshold voltage detection period, the first gate signal is at the active level, each of the second gate signal, the third gate signal and the emission signal is at the non-active level, and the data voltage is applied to the data line.

In an embodiment, during a second initialization period that follows the data write period, the third gate signal is at the active level, and each of the first gate signal, the second gate signal and the emission signal is at the non-active level.

In an embodiment, during an emission period that follows the second initialization period, the emission signal is at the active level, and each of the first, second, and third gate signals is at the non-active level.

In an embodiment, the emission signal, when at the non-active level, has the same value as or a smaller value than when the first gate signal is at the non-active level.

In an embodiment, a capacitance of the second capacitor is greater than a capacitance of the first capacitor.

In an embodiment, the pixel circuit further includes a fifth transistor connected between the second node and an anode of the light-emitting element, wherein the fourth transistor is connected between the anode of the light-emitting element and the initialization voltage line.

In an embodiment, the pixel circuit further includes a first gate line connected to a gate electrode of the second transistor, a second gate line connected to a gate electrode of the third transistor, a third gate line connected to a gate electrode of the fourth transistor, and a fourth gate line connected to a gate electrode of the fifth transistor.

In an embodiment, the data line transmits a data voltage, the emission line transmits an emission signal, the first gate line transmits a first gate signal, the second gate line transmits a second gate signal, the third gate line transmits a third gate signal, and the fourth gate line transmits a fourth gate signal.

In an embodiment, during a first initialization period, each of the second, third, and fourth gate signals is at the active level, and each of the first gate signal and the emission signal is at the non-active level.

In an embodiment, during a threshold voltage detection period that follows the first initialization period, each of the second gate signal and the emission signal is at the active level, and each of the first, third, and fourth gate signals is at the non-active level.

In an embodiment, during a data write period that follows the threshold voltage detection period, the first gate signal is at the active level, each of the second gate signal, the third gate signal, the fourth gate signal, and the emission signal is at the non-active level, and the data voltage is applied to the data line.

In an embodiment, during a second initialization period that follows the data write period, each of the third and fourth gate signals is at the active level, and each of the first gate signal, the second gate signal, and the emission signal is at the non-active level.

In an embodiment, during an emission period that follows the second initialization period, each of the emission signal and the fourth gate signal is at the active level, and each of the first, second, and third gate signals is at the non-active level.

According to an embodiment, a display device includes a pixel circuit and a light-emitting element connected between a second node of the pixel circuit and a common voltage line, wherein the pixel circuit includes a first transistor, which is connected between a driving voltage line and the second node and has a gate electrode connected to a first node and a counter gate electrode connected to an emission line, a second transistor, which has a gate electrode connected to a first gate line and is connected between a data line and the first node, a third transistor, which has a gate electrode connected to a second gate line and is connected between a reference voltage line and the first node, a fourth transistor, which has a gate electrode connected to a third gate line and is connected between the second node and an initialization voltage line, a first capacitor, which is connected between the first and second nodes, and a second capacitor, which is connected between the second node and the driving voltage line, where during a first initialization period, each of a second gate signal from the second gate line and a third gate signal from the third gate line is at an active level, and each of a first gate signal from the first gate line and an emission signal from the emission line is at a non-active level, where during a threshold voltage detection period that follows the first initialization period, each of the second gate signal and the emission signal is at the active level, and each of the first and third gate signals is at the non-active level, where during a data write period that follows the threshold voltage detection period, the first gate signal is at the active level, each of the second gate signal, the third gate signal, and the emission signal is at the non-active level, and a data voltage is applied to the data line, where during a second initialization period that follows the data write period, the third gate signal is at the active level, and each of the first gate signal, the second gate signal, and the emission signal is at the non-active level, and where during an emission period that follows the second initialization period, the emission signal is at the active level, and each of the first, second, and third gate signals is at the non-active level.

According to an embodiment, a display device includes a pixel circuit and a light-emitting element connected between a second node of the pixel circuit and a common voltage line, wherein the pixel circuit includes a first transistor, which is connected between a driving voltage line and the second node and has a gate electrode connected to a first node and a counter gate electrode connected to an emission line, a second transistor, which has a gate electrode connected to a first gate line and is connected between a data line and the first node, a third transistor, which has a gate electrode connected to a second gate line and is connected between a reference voltage line and the first node, a fourth transistor, which has a gate electrode connected to a third gate line and is connected between an anode of the light-emitting element and an initialization voltage line, a fifth transistor, which has a gate electrode connected to a fourth gate line and is connected between the second node and the anode of the light-emitting element, a first capacitor, which is connected between the first and second nodes, and a second capacitor, which is connected between the second node and the driving voltage line, where during a first initialization period, each of a second gate signal from the second gate line, a third gate signal from the third gate line, and a fourth gate signal from the fourth gate line is at an active level, and each of a first gate signal from the first gate line and an emission signal from the emission line is at a non-active level, where during a threshold voltage detection period that follows the first initialization period, each of the second gate signal and the emission signal is at the active level, and each of the first, third, and fourth gate signals is at the non-active level, where during a data write period that follows the threshold voltage detection period, the first gate signal is at the active level, and each of the second gate signal, the third gate signal, the fourth gate signal, and the emission signal is at the non-active level, and a data voltage is applied to the data line, where during a second initialization period that follows the data write period, each of the third and fourth gate signals is at the active level, and each of the first gate signal, the second gate signal, and the emission signal is at the non-active level, and where during an emission period that follows the second initialization period, each of the emission signal and the fourth gate signal is at the active level, and each of the first, second, and third gate signals is at the non-active level.

However, the invention is not restricted to those embodiments set forth herein. The above and other aspects of the invention will become more apparent to one of ordinary skill in the art to which the invention pertains by referencing the detailed description of the invention given below.

According to the aforementioned and other embodiments of the invention, since the turn-on and turn-off of a first transistor are controlled by an emission signal, a separate transistor (e.g., an emission control transistor) for controlling the driving current of a driving transistor may be omitted. Therefore, each pixel of a display device can control the driving current of the driving transistor while including fewer transistors. Therefore, each pixel can be advantageously applied to a high-density and high-resolution display device.

The embodiments of the invention are not limited to the above-described embodiments, and other embodiments which are not described herein will become apparent to those skilled in the art from the following description.

### BRIEF DESCRIPTION OF THE DRAWINGS

The above and other aspects and features of the invention will become more apparent by describing in detail exemplary embodiments thereof with reference to the attached drawings, in which:

FIG. 1 is a perspective view of a display device, according to an embodiment;

FIG. 2 is a cross-sectional side view of the display device, according to an embodiment;

FIG. 3 is a plan view illustrating a display unit of the display device, according to an embodiment;

FIG. 4 is a block diagram illustrating a display panel and a display driver of a display device, according to an embodiment;

FIG. 5 is a circuit diagram of an exemplary pixel of the display device, according to an embodiment;

FIG. 6 is a timing diagram for explaining first, second, and third gate signals and an emission signal of FIG. 5, according to an embodiment;

FIG. 7 is a circuit diagram for explaining an operation of the display device of FIG. 5 during a first initialization period of FIG. 6, according to an embodiment;

FIG. 8 is a circuit diagram for explaining an operation of the display device of FIG. 5 during a threshold voltage detection period of FIG. 6, according to an embodiment;

FIG. 9 is a circuit diagram for explaining an operation of the display device of FIG. 5 during a data write period of FIG. 6, according to an embodiment;

FIG. 10 is a circuit diagram for explaining an operation of the display device of FIG. 5 during a second initialization period of FIG. 6, according to an embodiment;

FIG. 11 is a circuit diagram for explaining an operation of the display device of FIG. 5 during an emission period of FIG. 6, according to an embodiment;

FIG. 12 is a circuit diagram of another exemplary pixel of the display device according to an embodiment;

FIG. 13 is a timing diagram for explaining a first gate signal, a second gate signal, a third gate signal, a fourth gate signal, and an emission signal of FIG. 12, according to an embodiment;

FIG. 14 is a circuit diagram for explaining the operation of the display device of FIG. 12 during first initialization period of FIG. 13, according to an embodiment;

FIG. 15 is a circuit diagram for explaining the operation of the display device of FIG. 12 during a threshold voltage detection period of FIG. 13, according to an embodiment;

FIG. 16 is a circuit diagram for explaining the operation of the display device of FIG. 12 during a data write period of FIG. 13, according to an embodiment;

FIG. 17 is a circuit diagram for explaining the operation of the display device of FIG. 12 during a second initialization period of FIG. 13, according to an embodiment;

FIG. 18 is a circuit diagram for explaining the operation of the display device of FIG. 12 during an emission period of FIG. 13, according to an embodiment; and

FIG. 19 is a cross-sectional view of a display device, according to an embodiment.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

It will also be understood that when a layer is referred to as being disposed “on”, “connected to” or “coupled to” another element, layer or substrate, it can be directly on the other element, layer or substrate, or intervening elements, layers or substrates may also be present. Likewise, those referred to as “Below”, “Left”, and “Right” include cases where they are directly adjacent to other elements or cases where another layer or other material is interposed. To this end, the term “connected” may refer to physical, electrical, and/or fluid connection, with or without intervening elements.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

Features of various embodiments of the present disclosure may be combined partially or totally. As will be clearly appreciated by those skilled in the art, technically various interactions and operations are possible. Various embodiments can be practiced individually or in combination.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the invention. Further, the blocks, units, parts, and/or modules of some embodiments may be physically combined into more complex blocks, units, parts, and/or modules without departing from the scope of the invention.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the invention will be described in detail with reference to the accompanying drawings.

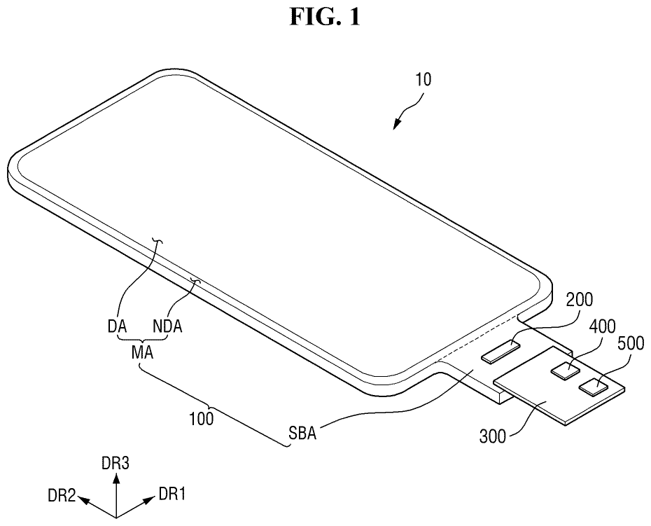

FIG. 1 is a perspective view of a display device, according to an embodiment.

In an embodiment and referring to FIG. 1, a display device 10 is applicable to a portable electronic device such as a mobile phone, a smart phone, a tablet personal computer (PC), a mobile communication terminal, an electronic notepad, an e-book reader, a portable multimedia player (PMP), a navigation system, or an ultra-mobile PC. For example, in one embodiment, the display device 10 may be applied to a display unit of a television (TV), a laptop computer, a monitor, an advertising board, or an Internet of Things (IoT) device. In another embodiment, the display device 10 may be applied to a wearable device such as a smartwatch, a watch phone, an eyewear display, or a head-mounted display (HMD).

In an embodiment, the display device 10 may have a planar shape similar to a rectangle. For example, the display device 10 may have a planar shape similar to a rectangle with short sides in a first direction DR1 and long sides in a second direction DR2. The corners where the short sides in the first direction DR1 and the long sides in the second direction DR2 meet may be curved with a predetermined curvature or may be formed at a right angle. The planar shape of the display device 10 is not particularly limited and may be formed similarly to other polygons, a circle, or an ellipse.

The display device 10 may include a display panel 100, a display driving unit 200, a circuit board 300, a touch driving unit 400, and a power supply unit 500.

The display panel 100 may include a main area MA and a sub-area SBA.

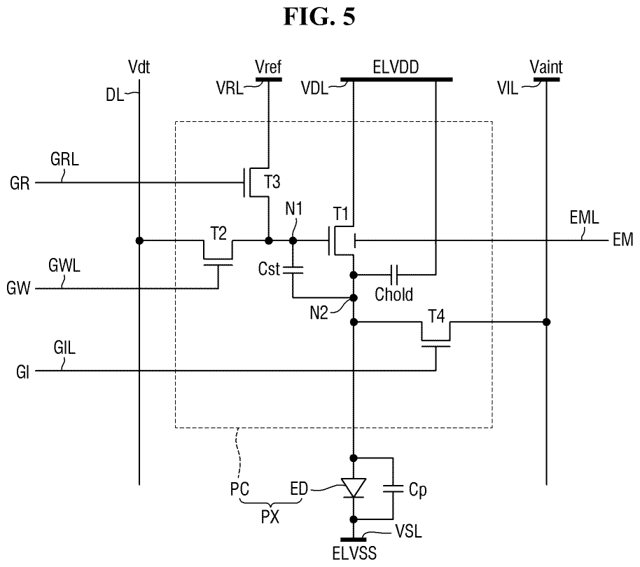

The main area MA may include a display area DA, which is equipped with pixels for displaying an image, and a non-display area NDA, which is disposed around the display area DA. The display area DA may emit light from a plurality of emission areas or opening areas. For example, in an embodiment, the display panel 100 may include pixel circuits, which include switching devices, a pixel-defining film, which defines the emission or opening areas, and self-light-emitting elements ED (See FIG. 5).

For example, the self-emitting elements ED may include organic light-emitting diodes (OLEDs) containing organic light emitting layers, quantum dot light-emitting diodes (LEDs) containing a quantum dot emitting layer, and/or inorganic LEDs containing an inorganic semiconductor, and micro-LEDs, but the invention is not limited thereto.

The non-display area NDA may be an area outside the display area DA. The non-display area NDA may be defined as an edge area of the main area MA of the display panel 100. The non-display area NDA may include a gate driver (not illustrated), which supplies gate signals to gate lines, and fan-out lines (not illustrated), which connect the display driving unit 200 and the display area DA.

The sub-area SBA may extend from one side of the main area MA and may include a flexible material that is bendable, foldable, or rollable. For example, when the sub-area SBA is bent, the sub-area SBA may overlap with the main area MA in a thickness direction (e.g., in a third direction DR3). The sub-area SBA may include the display driving unit 200, and a pad unit, which is connected to the circuit board 300. In another embodiment, the sub-area SBA may be omitted, and the display driving unit 200 and the pad unit may be disposed in the non-display area NDA.

In an embodiment, the display driving unit 200 may output signals and voltages to drive the display panel 100. The display driving unit 200 may supply data voltages to data lines. The display driving unit 200 may supply power voltages to power lines and supply gate control signals to the gate driver. The display driving unit 200 may be formed as an integrated circuit (IC) and may be mounted on the display panel 100 using a chip-on-glass (COG), chip-on-plastic (COP), or ultrasonic bonding method. For example, in an embodiment, the display driving unit 200 may be disposed in the sub-area SBA and may be overlapping with the main area MA in the thickness direction (or in the third direction DR3) due to bending of the sub-area SBA. In another embodiment, the display driving unit 200 may be mounted on the circuit board 300.

In an embodiment, the circuit board 300 may be attached to the pad unit of the display panel 100 using an anisotropic conductive film (ACF) and lead lines of the circuit board 300 may be electrically connected to the pad unit of the display panel 100. The circuit board 300 may be a flexible printed circuit board (FPCB), a printed circuit board (PCB), or a flexible film such as a chip on film (COF).

In an embodiment, the touch driving unit 400 may be mounted on the circuit board 300 and may be electrically connected to a touch sensing unit of the display panel 100. The touch driving unit 400 may supply touch driving signals to a plurality of touch electrodes of the touch sensing unit and sense changes in capacitance between the touch electrodes. For example, the touch driving signals may be pulse signals with a predetermined frequency. The touch driving unit 400 may determine the presence and coordinates of input based on changes in capacitance between the touch electrodes. The touch driving unit 400 may be formed as an IC.

In an embodiment, the power supply unit 500 may be disposed on the circuit board 300 to supply power voltages to the display driving unit 200 and the display panel 100. The power supply unit 500 may generate driving voltages that are supplied to driving voltage lines VDL, generate initialization voltages that are supplied to initialization voltage lines VIL, generate reference voltages that are supplied to reference voltage lines VRL, and generate common voltages that are supplied to common voltage lines. In an embodiment, the common voltage of the common voltage line may be supplied to a common electrode that is shared in common with the light-emitting elements ED of the pixels. The driving voltages may be high-potential voltages for driving the light-emitting elements ED, while the common voltages may be low-potential voltages for driving the light-emitting elements ED.

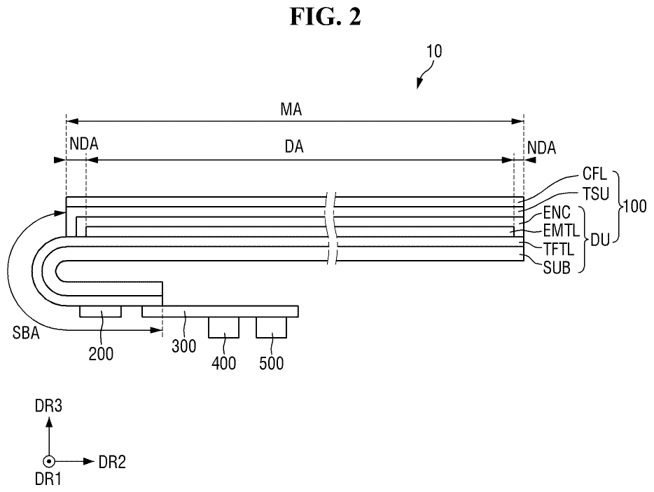

FIG. 2 is a cross-sectional view illustrating the display device, according to an embodiment.

In an embodiment and referring to FIG. 2, the display panel 100 may include a display unit DU, a touch sensing unit TSU, and a color filter layer CFL. The display unit DU may include a substrate SUB, a thin-film transistor (TFT) layer TFTL, a light-emitting element layer EMTL, and an encapsulation layer ENC.

In an embodiment, the substrate SUB may be a base substrate or base member and may be a flexible substrate that is bendable, foldable, or rollable. For example, in one embodiment, the substrate SUB may include a polymer resin such as polyimide (PI), but the present disclosure is not limited thereto. In another embodiment, the substrate SUB may include a glass or metal material.

In an embodiment, the TFT layer TFTL may be disposed on the substrate SUB and may include a plurality of TFTs, which form the pixel circuits of the pixels. The TFT layer TFTL may further include gate lines, data lines, power lines, gate control lines, fan-out lines, which connect the display driving unit 200 and the data lines, and lead lines, which connect the display driving unit 200 and the pad unit. Each of the TFTs may include a semiconductor region, a source electrode, a drain electrode, and a gate electrode. For example, if the gate driver is formed on one side of the non-display area NDA of the display panel 100, the gate driver may include the TFTs.

The TFT layer TFTL may be disposed in the display area DA, the non-display area NDA, and the sub-area SBA. The TFTs, gate lines, data lines, and power lines of the TFT layer TFTL may be disposed in the display area DA. The gate control lines and fan-out lines of the TFT layer TFTL may be disposed in the non-display area NDA and the lead lines of the TFT layer TFTL may be disposed in the sub-area SBA.

In an embodiment, the light-emitting element layer EMTL may be disposed on the TFT layer TFTL and may include the light-emitting elements ED, in which pixel electrodes, emission layers, and the common electrode are sequentially stacked to emit light, and the pixel-defining film, which defines the pixels. The light-emitting elements ED of the light-emitting element layer EMTL may be disposed in the display area DA.

For example, in an embodiment, the emission layers may be organic emission layers containing an organic material and each of the emission layers may include a hole transport layer, an organic light-emitting layer, and an electron transport layer. When the pixel electrodes receive a predetermined voltage through the TFTs of the TFT layer TFTL and the common electrode receives a cathode voltage, then holes and electrons may move through the hole transport layers and the electron transport layers, respectively, and combine in the organic emission layers to emit light. For example, the pixel electrodes may be, but are not limited to, anodes, and the common electrode may be, but is not limited to, a cathode.

In another embodiment, the light-emitting elements ED may include quantum dot LEDs containing quantum dot emission layers, inorganic LEDs containing an inorganic semiconductor, or micro-LEDs.

In an embodiment, the encapsulation layer ENC may cover the top and sides of the light-emitting element layer EMTL and may protect the light-emitting element layer EMTL. The encapsulation layer ENC may include at least one inorganic film and at least one organic film for encapsulating the light-emitting element layer EMTL.

In an embodiment, the touch sensing unit TSU may be disposed on the encapsulation layer ENC and may include a plurality of touch electrodes for detecting user touch input using a capacitance method, and touch lines connecting the touch electrodes and the touch driving unit 400. For example, the touch sensing unit TSU may sense user touch input using a mutual capacitance or self-capacitance method.

In another embodiment, the touch sensing unit TSU may be disposed on a separate substrate placed on the display unit DU. In this embodiment, the substrate supporting the touch sensing unit TSU may be a base member encapsulating the display unit DU.

The touch electrodes of the touch sensing unit TSU may be disposed in a touch sensor area which overlaps the display area DA and the touch lines of the touch sensing unit TSU may be disposed in a touch peripheral area which overlaps the non-display area NDA.

In an embodiment, the color filter layer CFL may be disposed on the touch sensing unit TSU and may include a plurality of color filters corresponding to the emission areas. Each of the color filters may selectively transmit light of a particular wavelength and block or absorb light of other wavelengths. The color filter layer CFL may absorb some of light entering from the outside of the display device 10 to reduce reflection caused by external light. Therefore, the color filter layer CFL can prevent color distortion caused by the reflection of external light.

As the color filter layer CFL is disposed directly on the touch sensing unit TSU, the display device 10 may not need a separate substrate for the color filter layer CFL. Therefore, the thickness of the display device 10 can be relatively reduced.

In an embodiment, the sub-area SBA of the display panel 100 may extend from one side of the main area MA and may include a flexible material that is bendable, foldable, or rollable. For example, when the sub-area SBA is bent, the sub-area SBA may overlap with the main area MA in the thickness direction (or in the third direction DR3). The sub-area SBA may include the pad unit, which is electrically connected to the display driving unit 200 and the circuit board 300.

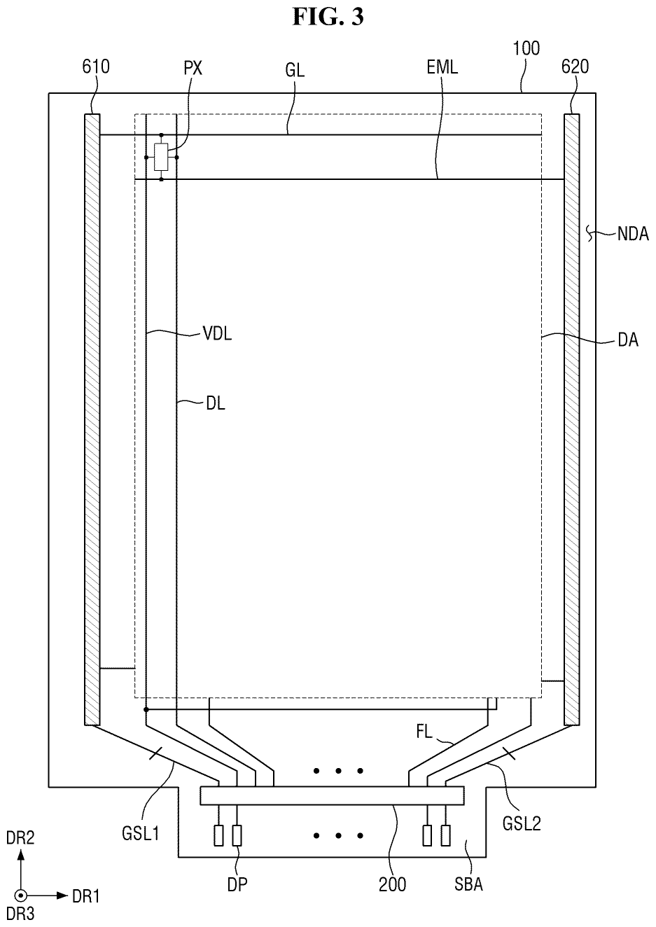

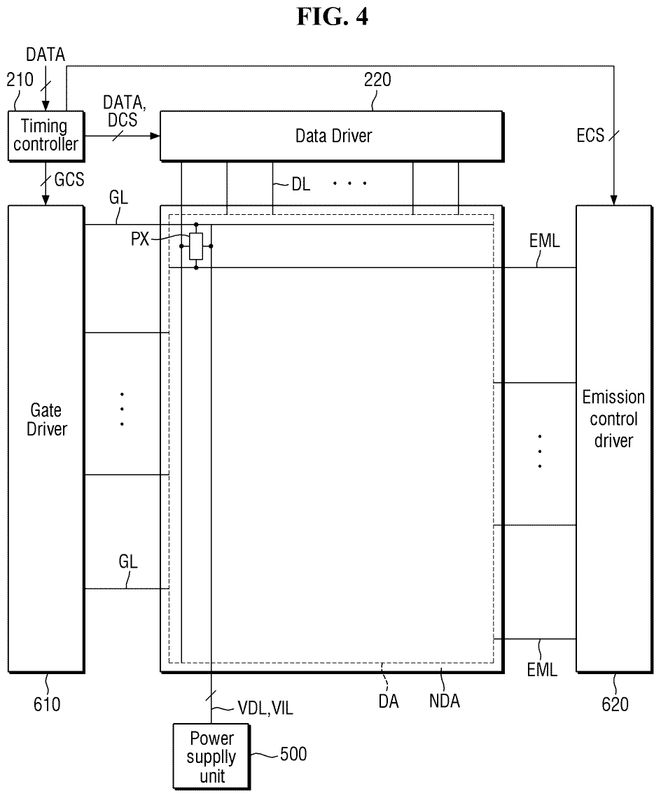

FIG. 3 is a plan view illustrating the display unit of the display device, according to an embodiment, and FIG. 4 is a block diagram illustrating a display panel and a display driver, according to an embodiment.

Referring to FIGS. 3 and 4, the display panel 100 may include the display area DA and the non-display area NDA.

In an embodiment, the display area DA may include a plurality of pixels PX, a plurality of driving voltage lines VDL, a plurality of gate lines GL, a plurality of emission lines EML, a plurality of data lines DL of a plurality of common voltage lines (“VSL” of FIG. 5), where the driving voltage lines VDL, the gate lines GL, the emission lines EML, and the data lines DL may be connected to the pixels PX.

Specifically, the pixels PX may be connected to the gate lines GL, the data lines DL, the emission lines EML, the driving voltage lines VDL, and the common voltage lines VSL and each of the pixels PX may include at least one transistor, a light-emitting element ED, and a capacitor.

In an embodiment, the gate lines GL may extend in the first direction DR1 and may be spaced apart from one another in the second direction DR2, which intersects the first direction DR1. The gate lines GL may be arranged along the second direction DR2 and may sequentially supply gate signals to the pixels PX.

In an embodiment, the emission lines EML may extend in the first direction DR1 and may be spaced apart from one another in the second direction DR2. The emission lines EML may be arranged along the second direction DR2 and may sequentially supply emission signals to the pixels PX.

In an embodiment, the data lines DL may extend in the second direction DR2 and may be spaced apart from one another in the first direction DR1. The data lines DL may be arranged along the first direction DR1 and may supply data voltages to the pixels PX. The data voltages may determine the luminance of the pixels PX.

In an embodiment, the driving voltage lines VDL may extend in the second direction DR2 and may be spaced apart from one another in the first direction DR1. The driving voltage lines VDL may be arranged along the first direction DR1 and may supply a first driving voltage to the pixels PX. The first driving voltage may be a high-potential voltage for driving the light-emitting elements ED of the pixels PX.

In an embodiment, the non-display area NDA may surround the display area DA and may include a gate driver 610, an emission control driver 620, fan-out lines FL, a first gate control line GSL1, and a second gate control line GSL2.

The fan-out lines FL may extend from the display driving unit 200 to the display area DA and may supply data voltages received from the display driving unit 200 to the data lines DL.

The first gate control line GSL1 may extend from the display driving unit 200 to the gate driver 610 and may supply gate control signals GCS received from the display driving unit 200 to the gate driver 610.

The second gate control line GSL2 may extend from the display driving unit 200 to the emission control driver 620 and may supply emission control signals ECS received from the display driving unit 200 to the emission control driver 620.

In an embodiment, the sub-area SBA may extend from one side of the non-display area NDA and may include the display driving unit 200 and pads DP. The pads DP may be disposed more adjacent than the display driving unit 200 to one edge of the sub-area SBA and may be electrically connected to the circuit board 300 via an ACF.

In an embodiment, the display driving unit 200 may include a timing controller 210 and a data driver 220.

The timing controller 210 may receive digital video data DATA and timing signals from the circuit board 300. Based on the timing signals, the timing controller 210 may generate data control signals DCS to control the operation timing of the data driver 220, may generate the gate control signals GCS to control the operation timing of the gate driver 610, and may generate emission control signals ECS to control the operation timing of the emission control driver 620. The timing controller 210 may also supply the gate control signals GCS to the gate driver 610 via the first gate control line GSL1. The timing controller 210 may supply the emission control signals ECS to the emission control driver 620 via the second gate control line GSL2. The timing controller 210 may supply the digital video data DATA and the data control signals DCS to the data driver 220.

The data driver 220 may convert the digital video data DATA into analog data voltages and supply the digital video data DATA to the data lines DL via the fan-out lines FL. The gate signals from the gate driver 610 may select the pixels PX to which the data voltages are to be supplied, and the selected pixels PX may receive the data voltages via the data lines DL.

In an embodiment, the power supply unit 500, which is disposed on the circuit board 300, may supply power voltages to the display driving unit 200 and the display panel 100. The power supply unit 500 may generate driving voltages which are supplied to the driving voltage lines VDL, generate initialization voltages which are supplied to the initialization voltage lines VIL, and may generate common voltages which are supplied to the common electrode that is shared in common by the light-emitting elements ED of the pixels PX.

In an embodiment, the gate driver 610 may be disposed on one side of the display panel 100 to located outside of the display area DA or one side of the non-display area NDA, and the emission control driver 620 may be disposed on the other side of the display panel 100 to be located outside the display area DA or the other side of the non-display area NDA. However, the invention is not limited to this. For example, in another embodiment, the gate driver 610 and the emission control driver 620 may be disposed on either side of the non-display area NDA.

The gate driver 610 may include a plurality of transistors that generate gate signals based on the gate control signals GCS. The emission control driver 620 may include a plurality of transistors that generate emission signals based on the emission control signals ECS. For example, the transistors in each of the gate driver 610 and the emission control driver 620 may be formed on the same layer as the transistors of the pixels PX. The gate driver 610 supplies the gate signals to the gate lines GL, while the emission control driver 620 supplies emission signals to the emission lines EML.

FIG. 5 is a circuit diagram of an exemplary pixel of the display device, according to an embodiment.

In an embodiment and referring to FIG. 5, a pixel PX may be connected to a first gate line GWL, a second gate line GRL, a third gate line GIL, an emission line EML, a data line DL, a driving voltage line VDL, a common voltage line VSL, a reference voltage line VRL, and an initialization voltage line VIL.

In an embodiment, the pixel PX may include a pixel circuit PC and a light-emitting element ED. The pixel circuit PC may include a first transistor T1, a second transistor T2, a third transistor T3, and a fourth transistor T4, a first capacitor Cst, and a second capacitor Chold.

The first transistor T1 may include a gate electrode, a source electrode, and a drain electrode and may control a source-drain current (or a driving current) depending on a data voltage applied to its gate electrode. The driving current, flowing through the channel region of the first transistor T1, may be proportional to the square of the difference between a source-gate voltage, which is the voltage between the source and gate electrodes of the first transistor T1, and a threshold voltage of the first transistor T1, given by:

$$Isd = k \times {( Vsg - Vth )}^{2} ,$$

where Isd represents a driving current, k represents a proportionality coefficient determined by the structure and physical characteristics of the first transistor T1, Vsg represents the source-gate voltage of the first transistor T1, and Vth represents the threshold voltage of the first transistor T1. The drain electrode of the first transistor T1 may be connected to a driving voltage line VDL, which transmits a driving voltage ELVDD, for example, a high-potential voltage.

In an embodiment, the first transistor T1 may be a double-gate transistor having two gate electrodes, e.g., a gate electrode and a counter gate electrode. The gate electrode and the counter gate electrode may be disposed to be facing each other in different layers with an active layer disposed therebetween. The gate electrode of the first transistor T1 may be electrically connected to a first node N1, the counter gate electrode of the first transistor T1 may be connected to the emission line EML, the drain electrode of the first transistor T1 may be electrically connected to the driving voltage line VDL, and the source electrode of the first transistor T1 may be electrically connected to a second node N2. The first transistor T1 may be controlled by an emission signal EM applied to the counter gate electrode of the first transistor T1. For example, when the emission signal EM applied to the counter gate electrode of the first transistor T1 is at a non-active level (for example, at a low voltage), the first transistor T1 may be turned off regardless of the voltage applied to the gate electrode of the first transistor T1. In one embodiment, when the emission signal EM is at the non-active level and is applied to the counter gate electrode of the first transistor T1, the threshold voltage of the first transistor T1 may be shifted to increase. Furthermore, in another embodiment, when an emission signal EM is at an active level and is applied to the counter gate electrode of the first transistor T1, the threshold voltage of the first transistor T1 may be shifted to decrease.

In an embodiment, since the turn-on and turn-off of the first transistor T1, which is a driving transistor, is controlled by the emission signal EM, a separate transistor (e.g., an emission control transistor) for controlling the driving current of the first transistor T1 may be omitted. Therefore, the pixel PX requires fewer transistors while still allowing for control of the driving current of the first transistor T1. Thus, the pixel PX can be advantageously applied to a high-density/high-resolution display device 1.

In an embodiment, the light-emitting element ED may receive a driving current to emit light, where the luminance or brightness of the light-emitting element ED may be proportional to the magnitude of the driving current. The light-emitting element ED may be an OLED including first and second electrodes and an organic emission layer disposed between the first and second electrodes. In another embodiment, the light-emitting element ED may be an inorganic light-emitting element including first and second electrodes and an inorganic semiconductor disposed between the first and second electrodes. In still another embodiment, the light-emitting element ED may be a quantum dot light-emitting element including first and second electrodes and a quantum dot emission layer disposed between the first and second electrodes. In still yet another embodiment, the light-emitting element ED may be a micro-LED. The first electrode of the light-emitting element ED may be electrically connected to the second node N2, and the second electrode of the light-emitting element ED may be connected to the common voltage line VSL. The second electrode of the light-emitting element ED may receive a common voltage ELVSS (e.g., a low-potential voltage) from the common voltage line VSL.

In an embodiment, the second transistor T2 may be turned on by a first gate signal GW from the first gate line GWL, thereby electrically connecting the data line DL and the first node N1, which is the gate electrode of the first transistor T1. As the second transistor T2 is turned on based on the first gate signal GW, the second transistor T2 may supply a data voltage to the first node N1. The gate electrode of the second transistor T2 may be electrically connected to the first gate line GWL, the drain electrode of the second transistor T2 may be electrically connected to the data line DL, and the source electrode of the second transistor T2 may be electrically connected to the first node N1.

In an embodiment, the third transistor T3 may be turned on by a second gate signal GR from the second gate line GRL, thereby electrically connecting the first node N1 and the reference voltage line VRL. The gate electrode of the third transistor T3 may be electrically connected to the second gate line GRL, the drain electrode of the third transistor T3 may be electrically connected to the first node N1, and the source electrode of the third transistor T3 may be electrically connected to the reference voltage line VRL. The reference voltage line VRL may transmit a reference voltage.

In an embodiment, the fourth transistor T4 may be turned on by a third gate signal GI from the third gate line GIL, thereby electrically connecting the second node N2 and the initialization voltage line VIL. The fourth transistor T4 may be connected in series between the second node N2 and the initialization voltage line VIL. The gate electrode of the fourth transistor T4 may be electrically connected to the third gate line GIL, the drain electrode of the fourth transistor T4 may be electrically connected to the second node N2, and the source electrode of the fourth transistor T4 may be electrically connected to the initialization voltage line VIL. The initialization voltage line VIL may transmit an initialization voltage Vaint. In one embodiment, the initialization voltage Vaint may be less than the reference voltage Vref. Additionally, the initialization voltage Vaint may be less than the common voltage ELVSS.

In an embodiment, the first capacitor Cst may be electrically connected between the first node N1 and the second node N2. For example, the first electrode of the first capacitor Cst may be electrically connected to the first node N1, and the second electrode of the first capacitor Cst may be electrically connected to the second node N2. Accordingly, the first capacitor Cst may maintain a potential difference between the first and second nodes N1 and N2.

In an embodiment, the second capacitor Chold may be electrically connected between the second node N2 and the driving voltage ELVDD. For example, the first electrode of the second capacitor Chold may be electrically connected to the second node N2, and the second electrode of the capacitor Chold may be electrically connected to the driving voltage ELVDD. The capacitor Chold may maintain a potential difference between the second node N2 and the driving voltage ELVDD. In one embodiment, the capacitance of the second capacitor Chold may differ from that of the first capacitor Cst. For example, the capacitance of the second capacitor Chold may be greater than that of the first capacitor Cst.

Meanwhile, a capacitor Cp, which is connected between the anode and cathode of the light-emitting element, ED, may be a parasitic capacitor of the light-emitting element ED.

In an embodiment, at least one of the first, second, third, and fourth transistors T1, T2, T3, and T4, respectively, may be an n-type transistor including an oxide-based active layer. Transistors including an oxide-based active layer may have a coplanar structure where their gate electrodes are arranged on top. Transistors including an oxide-based active layer may output current flowing from their drain electrodes to source electrodes based on a gate high voltage applied to their gate electrodes.

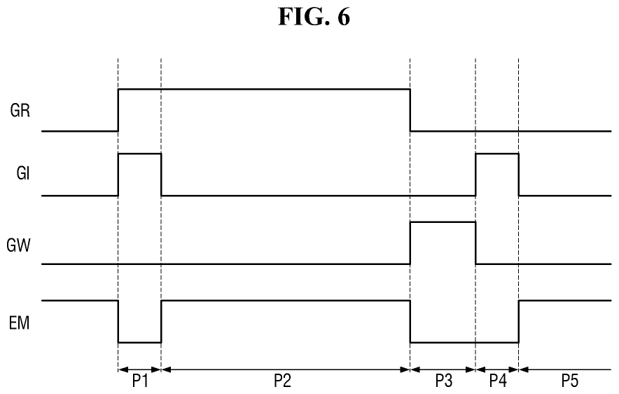

FIG. 6 is a timing diagram showing the first, second, and third gate signals GW, GR, and GI, respectively, and the emission signal EM of FIG. 5, according to an embodiment.

In an embodiment and referring to FIG. 6, the display device 10 may operate based on a first initialization period P1, a threshold voltage detection period P2, a data write period P3, a second initialization period P4, and an emission period P5.

In an embodiment, the first, second, and third gate signals GW, GR, and GI, respectively, and the emission signal EM may each be at an active level or a non-active level during each of the first initialization period P1, the threshold voltage detection period P2, the data write period P3, the second initialization period P4, and the emission period P5. Here, the active level of each of the first, second, and third gate signals GW, GR, and GI, respectively, and the emission signal EM may refer to a voltage level that can turn on the corresponding transistor when applied. In other words, when each of the first, second, and third gate signals GW, GR, and GI, respectively, and the emission signal EM are at the active level, they may have a greater voltage than the threshold voltage of the corresponding transistor. For example, the active level of each of the first, second, and third gate signals GW, GR, and GI, respectively, and the emission signal EM, applied to the gate electrode of the corresponding transistor, may refer to a high level (e.g., a positive level or a high voltage level) if the corresponding transistor is an n-type transistor.

In an embodiment, the non-active level of each of the first, second, and third gate signals GW, GR, and GI, respectively, and the emission signal EM may represent a voltage level capable of turning off the corresponding transistor. In other words, each of the first, second, and third gate signals GW, GR, and GI, respectively, and the emission signal EM at the non-active level may have a voltage that is lower than the threshold voltage of the corresponding transistor. For example, the non-active level of each of the first, second, and third gate signals GW, GR, and GI, respectively, and the emission signal EM, applied to the gate electrode of the corresponding transistor, may refer to a low level (e.g., a negative level or a low voltage level) if the corresponding transistor is an n-type transistor.

In another embodiment, if the corresponding transistor is a p-type transistor, the active level and non-active level of each of the first, second, and third gate signals GW, GR, and GI, respectively, and the emission signal EM, that is applied to the gate electrode of the corresponding transistor, may refer to a low level (e.g., a negative level or a low voltage level) and a high level (e.g., a positive level or a high voltage level), respectively.

In an embodiment, during the first initialization period P1, the second and third gate signals GR and GI, respectively, may each be at the active level. However, during the first initialization period P1, the first gate signal GW and the emission signal EM may each be at the non-active level.

During the threshold voltage detection period P2, the second gate signal GR and the emission signal EM may each be at the active level. However, during the threshold voltage detection period P2, the first gate signal GW and the third gate signal GI may each be at the non-active level.

During the data write period P3, the first gate signal GW may be at the active level. However, during the data write period P3, the second and third gate signals GR and GI, respectively, and the emission signal EM may each be at the non-active level. Additionally, during the data write period P3, a data voltage Vdt may be applied to the data line DL.

During the second initialization period P4, the third gate signal GI may be at the active level. However, during the second initialization period P4, the first and second gate signals GW and GR, respectively, and the emission signal EM may each be at the non-active level.

During the emission period P5, the emission signal EM may be at the active level. However, during the emission period P5, the first gate signal GW, the second gate signal GR, and the third gate signal GI may each be at the non-active level.

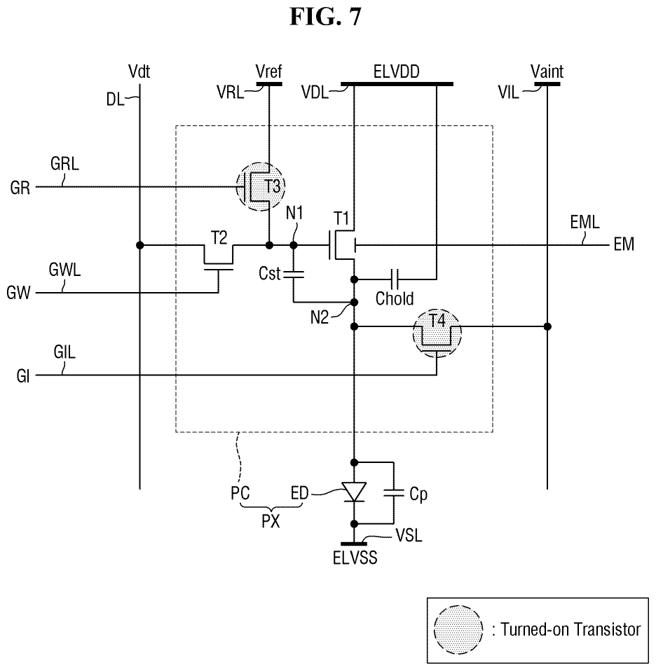

An embodiment of the operations of the display device 10 will hereinafter be described with reference to FIGS. 7 through 11, where in FIGS. 7 through 11, the dashed circles indicate turned-on transistors, while transistors without the dashed circles indicate turned-off transistors.

First, the operation of the display device 10 during the first initialization period P1 will hereinafter be described with reference to FIGS. 6 and 7, according to an embodiment, where FIG. 7 is a circuit diagram for explaining the operation of the display device 10 of FIG. 5 during the first initialization period P1 of FIG. 6.

As illustrated in FIG. 6, during the first initialization period P1, the second and third gate signals GR and GI, respectively, may each be at the active level. However, during the first initialization period P1, the first gate signal GW and the emission signal EM may each be at the non-active level.

The second gate signal GR, which is at the active level, may be applied to the gate electrode of the third transistor T3 through the second gate line GRL. Consequently, the third transistor T3 may be turned on.

The third gate signal GI, which is at the active level, may be applied to the gate electrode of the fourth transistor T4 through the third gate line GIL. Consequently, the fourth transistor T4 may be turned on.

The first gate signal GW, which is at the non-active level, may be applied to the gate electrode of the second transistor T2 through the first gate line GWL. Consequently, the second transistor T2 may be turned off.

The emission signal EM, which is at the non-active level, may be applied to the counter gate electrode of the first transistor T1 through the emission line EML. Consequently, the first transistor T1 may be turned off.

As the third transistor T3 is turned on, the reference voltage Vref may be applied to the first node N1 through the turned-on third transistor T3. Therefore, the gate electrode of the first transistor T1, which is connected to the first node N1, may be initialized to the reference voltage Vref.

As the fourth transistor T4 is turned on, the initialization voltage Vaint may be applied to the second node N2 through the turned-on fourth transistor T4. Consequently, the source electrode of the first transistor T1, connected to the second node N2, may be initialized to the initialization voltage Vaint.

The difference between the reference voltage Vref at the first node N1 and the initialization voltage Vaint at the second node N2, such as the gate-source voltage of the first transistor T1, may be greater than the threshold voltage of the first transistor T1. However, since the emission signal EM at the non-active level is applied to the counter gate electrode of the first transistor T1, as described above, the first transistor T1 may be turned off. For example, in an embodiment, when the emission signal EM applied to the counter gate electrode of the first transistor T1 is at the non-active level, the threshold voltage of the first transistor T1 may be shifted to increase, and as a result, the gate-source voltage of the first transistor T1 may become less than the increased threshold voltage of the first transistor T1. Therefore, when the emission signal EM is at the non-active level, the first transistor T1 can always remain turned off regardless of its gate-source voltage. In an embodiment, the emission signal EM at the non-active level may have a voltage that is less than or equal to a gate signal at the non-active level. For example, the voltage of the emission signal EM at the non-active level may be the same as or less than that of the first gate signal GW at the non-active level.

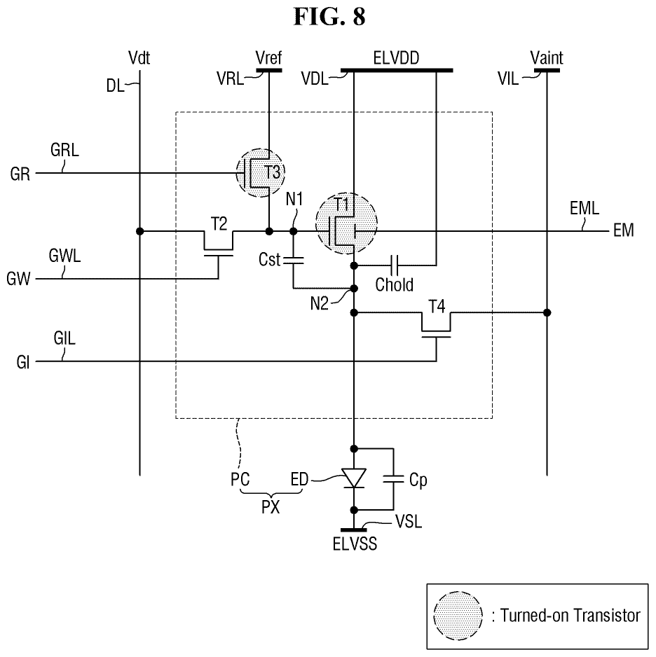

The operation of the display device 10 during the threshold voltage detection period P2 will hereinafter be described with reference to FIGS. 6 and 8, according to an embodiment, where FIG. 8 is a circuit diagram for explaining the operation of the display device 10 of FIG. 5 during the threshold voltage detection period P2 of FIG. 6.

In an embodiment and as illustrated in FIG. 6, during the threshold voltage detection period P2, the second gate signal GR and the emission signal EM may each be at the active level. However, during the threshold voltage detection period P2, the first and third gate signals GW and GI, respectively, may each be at the non-active level.

The second gate signal GR, which is at the active level, may be applied to the gate electrode of the third transistor T3 through the second gate line GRL. Consequently, the third transistor T3 may be turned on.

The emission signal EM, which is at the active level, may be applied to the counter gate electrode of the first transistor T1 through the emission line EML. Consequently, during the threshold voltage detection period P2, the first transistor T1 may be turned on and then turned off, as will be described later.

The first gate signal GW, which is at the non-active level, may be applied to the gate electrode of the second transistor T2 through the first gate line GWL. Consequently, the second transistor T2 may be turned off.

The third gate signal GI, which is at the non-active level, may be applied to the gate electrode of the fourth transistor T4 through the third gate line GIL. Consequently, the fourth transistor T4 may be turned off.

Accordingly, in an embodiment, through the turned-on third transistor T3, the reference voltage Vref may be applied to the first node N1, and as a result, the voltage of the gate electrode of the first transistor T1 may be maintained at the reference voltage Vref. The voltage of the source electrode of the first transistor T1 is the initialization voltage Vaint that is applied during the previous period (i.e., the first initialization period P1), and since the emission signal EM applied to the counter gate electrode of the first transistor T1 is at the active level, the first transistor T1 may be turned on during the threshold voltage detection period P2. Moreover, during the threshold voltage detection period P2, the second node N2 remains floating due to the turned-off fourth transistor T4, thereby allowing the voltage of the second node N2 to gradually increase due to the current flowing through the turned-on first transistor T1. In other words, as the fourth transistor T4 is turned off, the supply of the initialization voltage Vaint to the second node N2 is interrupted, causing the voltage of the second node N2 to rise and thereby gradually reducing the current flowing through the first transistor T1. Consequently, the gate-source voltage of the first transistor T1 gradually decreases until the first transistor T1 is turned off when its gate-source voltage reaches the threshold voltage of the first transistor T1. As such, the detected threshold voltage of the first transistor T1 may be reflected in the second node N2. Moreover, the detected threshold voltage of the first transistor T1 may be stored and maintained in the second node N2 by the first capacitor Cst.

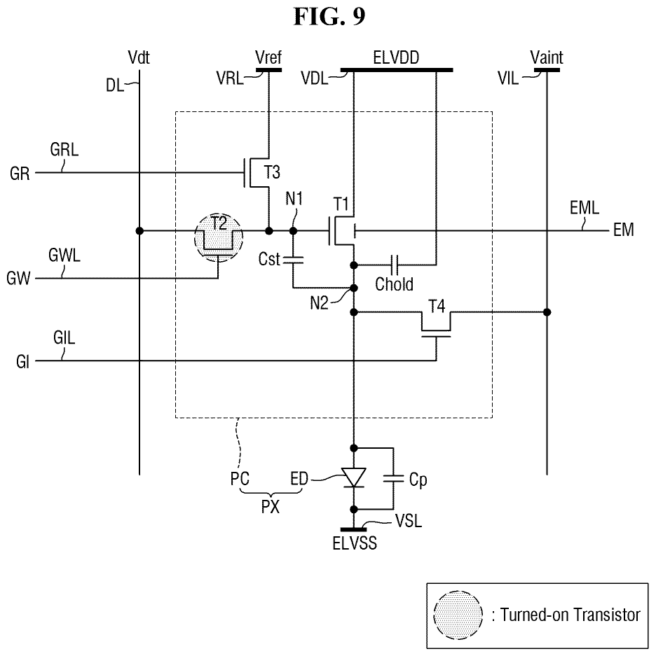

The operation of the display device 10 during the data write period P3 will hereinafter be described with reference to FIGS. 6 and 9, according to an embodiment, where FIG. 9 is a circuit diagram for explaining the operation of the display device 10 of FIG. 5 during the data write period P3 of FIG. 6.

In an embodiment and as illustrated in FIG. 6, during the data write period P3, the first gate signal GW may be at the active level. However, during the data write period P3, the second and third gate signals GR and GI, respectively, and the emission signal EM may each be at the non-active level. Moreover, during the data write period P3, the data voltage Vdt may be applied to the data line DL.

The first gate signal GW, which is at the active level, may be applied to the gate electrode of the second transistor T2 through the first gate line GWL. Consequently, the second transistor T2 may be turned on.

The second gate signal GR, which is at the non-active level, may be applied to the gate electrode of the third transistor T3 through the second gate line GRL. Consequently, the third transistor T3 may be turned off.

The third gate signal GI, which is at the non-active level, may be applied to the gate electrode of the fourth transistor T4 through the third gate line GIL. Consequently, the fourth transistor T4 may be turned off.

The emission signal EM, which is at the non-active level, may be applied to the counter gate electrode of the first transistor T1 through the emission line EML.

Accordingly, in an embodiment, as the second transistor T2 is turned on, the data voltage Vdt from the data line DL may be applied to the first node N1 through the turned-on second transistor T2. In other words, the data voltage Vdt from the data line DL may be applied to the gate electrode of the first transistor T1. The magnitude of the data voltage Vdt added to the voltage of the first node N1 may be determined by the ratio of the capacitance of the second capacitor Chold to the combined capacitance of the first capacitor Cst and the second capacitor Chold. For example, in an embodiment, the voltage added to the first node N1 may be determined as “data voltage Vdt*(capacitance of the second capacitor Chold/(capacitance of the first capacitor Cst+capacitance of the second capacitor Chold)),” where the data voltage Vdt may be a voltage with a predetermined grayscale (or brightness) for displaying an image. Moreover, during the data write period P3, the first transistor T1 may remain turned off due to the emission signal EM, which is at the non-active level, being applied to the counter gate electrode of the first transistor T1.

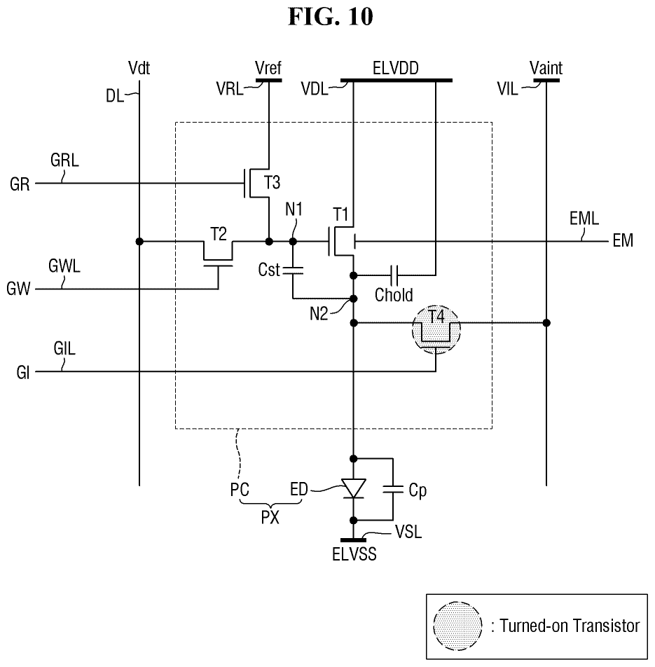

The operation of the display device 10 during the second initialization period P4 will hereinafter be described with reference to FIGS. 6 and 10, according to an embodiment, where FIG. 10 is a circuit diagram for explaining the operation of the display device 10 of FIG. 5 during the second initialization period P4 of FIG. 6.

As illustrated in FIG. 6, during the second initialization period P4, the third gate signal GI may be at the active level. However, during the second initialization period P4, the first gate signal GW, the second gate signal GR, and the emission signal EM may each be at the non-active level.

The third gate signal GI, which is at the active level, may be applied to the gate electrode of the fourth transistor T4 through the third gate line GIL. Consequently, the fourth transistor T4 may be turned on.

The first gate signal GW, which is at the non-active level, may be applied to the gate electrode of the second transistor T2 through the first gate line GWL. Consequently, the second transistor T2 may be turned off.

The second gate signal GR, which is at the non-active level may be applied to the gate electrode of the third transistor T3 through the second gate line GRL. Consequently, the third transistor T3 may be turned off.

The emission signal EM, which is at the non-active level, may be applied to the counter gate electrode of the first transistor T1 through the emission line EML.

Accordingly, in an embodiment, as the fourth transistor T4 is turned on, the initialization voltage Vaint from the initialization voltage line VIL may be applied to the second node N2 through the turned-on fourth transistor T4. Consequently, the voltage of the second node N2 may be initialized to the initialization voltage Vaint.

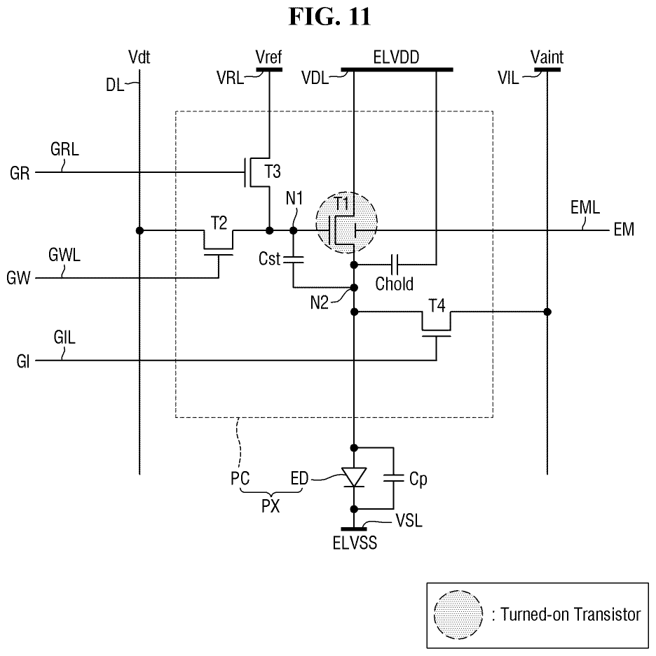

The operation of the display device 10 during the emission period P5 will hereinafter be described with reference to FIGS. 6 and 11, according to an embodiment, where FIG. 11 is a circuit diagram for explaining the operation of the display device 10 of FIG. 5 during the emission period P5 of FIG. 6.

As illustrated in FIG. 6, during the emission period P5, the emission signal EM may be at the active level. However, during the emission period P5, the first, second, and third gate signals GW, GR, and GI may each be at the non-active level.

The emission signal EM, which is at the active level, may be applied to the counter gate electrode of the first transistor T1 through the emission line EML.

The first gate signal GW, which is at the non-active level, may be applied to the gate electrode of the second transistor T2 through the first gate line GWL. Consequently, the second transistor T2 may be turned off.

The second gate signal GR, which is at the non-active level, may be applied to the gate electrode of the third transistor T3 through the second gate line GRL. Consequently, the third transistor T3 may be turned off.

The third gate signal GI, which is at the non-active level, may be applied to the gate electrode of the fourth transistor T4 through the third gate line GIL. Consequently, the fourth transistor T4 may be turned off.

During the emission period P5, the first transistor T1 may remain turned on due to the gate-source voltage being maintained by the first capacitor Cst and the emission signal EM at the active level.

Thus, during the emission period P5, the turned-on first transistor T1 may enable the driving voltage ELVDD to be applied to the first electrode of the light-emitting device ED, i.e., the second node N2, through the turned-on first transistor T1. The magnitude of the driving current flowing into the light-emitting device ED through the turned-on first transistor T1 may be determined based on the data voltage Vdt and the threshold voltage of the first transistor T1. Consequently, the driving current supplied to the light-emitting device ED may accurately reflect the magnitude of the data voltage Vdt. In other words, the driving current may be accurately compensated for by the threshold voltage of the first transistor T1. Thus, by compensating for the threshold voltage of the first transistor T1 of each pixel PX, the driving current of each pixel PX can be determined, thereby minimizing brightness deviations between pixels PX according to the deviations in the threshold voltage of the first transistor T1 between the pixels PX. Therefore, the display quality of the display device 10 can be enhanced.

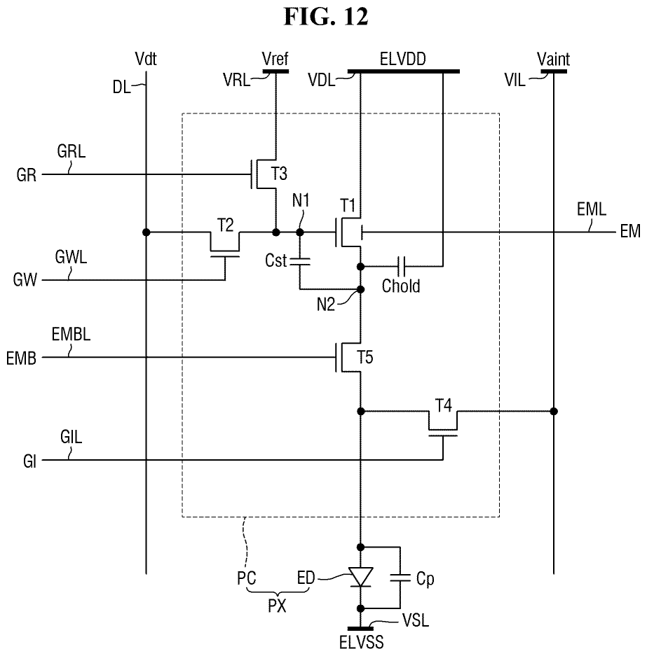

FIG. 12 is a circuit diagram of another exemplary pixel of the display device, according to an embodiment.

The pixel PX of FIG. 12 differs from its counterpart of FIG. 5 in that it further includes a fifth transistor T5, and will hereinafter be described, focusing mainly on the difference.

In an embodiment, the fifth transistor T5 may be turned on by a fourth gate signal EMB from a fourth gate line EMBL which electrically connects a second node N2 and the first electrode of a light-emitting element ED. The gate electrode of the fifth transistor T5 may be electrically connected to the fourth gate line EMBL, the drain electrode of the fifth transistor T5 may be electrically connected to the second node N2, and the source electrode of the fifth transistor T5 may be electrically connected to the first electrode of the light-emitting element ED.

The fifth transistor T5 may be an n-type transistor including an oxide-based active layer.

It should be appreciated that due to the fifth transistor T5, even if there is significant noise at the second node N2 (i.e., at the source electrode of a first transistor T1), the risk of a voltage setting at the second node N2 can be reduced.

Moreover, a fourth transistor T4 may be turned on by a third gate signal GI from a third gate line GIL which electrically connects the first electrode of the light-emitting element ED and an initialization voltage line VIL. The fourth transistor T4 may be connected in series between the first electrode of the light-emitting element ED and an initialization voltage line VIL, where the gate electrode of the fourth transistor T4 may be electrically connected to the third gate line GIL, the drain electrode of the fourth transistor T4 may be electrically connected to the first electrode of the light-emitting element ED, and the source electrode of the fourth transistor T4 may be electrically connected to the initialization voltage line VIL.

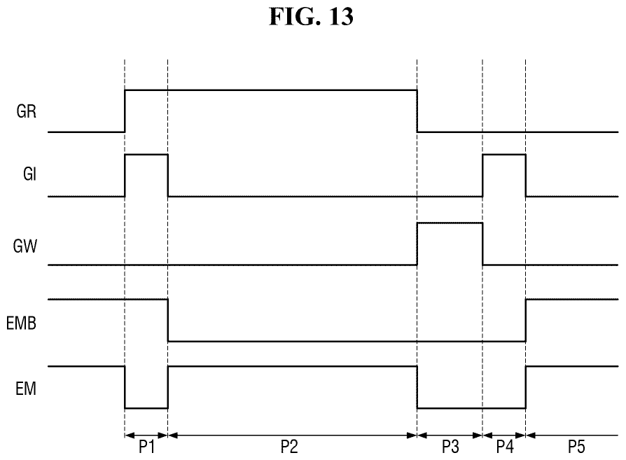

FIG. 13 is a timing diagram for explaining a first gate signal GW, a second gate signal GR, the third gate signal GI, the fourth gate signal EMB, and an emission signal EM of FIG. 12, according to an embodiment.

In an embodiment and referring to FIG. 13, the display device 10 may operate based on a first initialization period P1, a threshold voltage detection period P2, a data write period P3, a second initialization period P4, and an emission period P5.

During the first initialization period P1, the second, third, and fourth gate signals GR, GI, and EMB, respectively, may each be at the active level. However, during the first initialization period P1, the first gate signal GW and the emission signal EM may each be at the non-active level.

During the threshold voltage detection period P2, the second gate signal GR and the emission signal EM may each be at the active level. However, during the threshold voltage detection period P2, the first, third, and fourth gate signals GW, GI, and EMB, respectively, may each be at the non-active level.

During the data write period P3, the first gate signal GW may be at the active level. However, during the data write period P3, the second, third, and fourth gate signals GR, GI, and EMB, respectively, and the emission signal EM may each be at the non-active level. Moreover, during the data write period P3, a data voltage Vdt may be applied to a data line DL.

During the second initialization period P4, the third and fourth gate signals GI and EMB, respectively, may each be at the active level. However, during the second initialization period P4, the first and second gate signals GW and GR, respectively, and the emission signal EM may each be at the non-active level.

During the emission period P5, the emission signal EM and the fourth gate signal EMB may each be at the active level. However, during the emission period P5, the first, second, and third gate signals GW, GR, and GI, respectively, may each be at the non-active level.

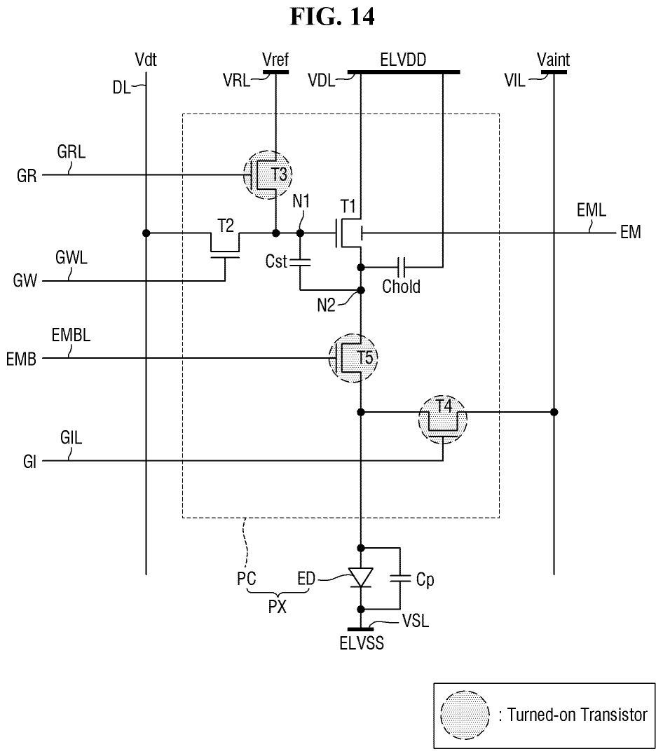

Operations of the display device 10 will hereinafter be described with reference to FIGS. 14 through 18, according to an embodiment. In FIGS. 14 through 18, dashed circles indicate turned-on transistors, while transistors without dashed circles indicate turned-off transistors.

First, the operation of the display device 10 during the first initialization period P1 will hereinafter be described with reference to FIGS. 13 and 14, according to an embodiment, where FIG. 14 is a circuit diagram for explaining the operation of the display device 10 of FIG. 12 during the first initialization period P1 of FIG. 13.

As illustrated in FIG. 13, during the first initialization period P1, the second, third, and fourth gate signals GR, GI, and EMB, respectively, may each be at the active level. However, during the first initialization period P1, the first gate signal GW and the emission signal EM may each be at the non-active level.

The second gate signal GR, which is at the active level, may be applied to the gate electrode of the third transistor T3 through the second gate line GRL. Consequently, the third transistor T3 may be turned on.

The third gate signal GI, which is at the active level, may be applied to the gate electrode of the fourth transistor T4 through the third gate line GIL. Consequently, the fourth transistor T4 may be turned on.

The fourth gate signal EMB, which is at the active level, may be applied to the gate electrode of the fifth transistor T5 through the fourth gate line EMBL. Consequently, the fifth transistor T5 may be turned on.

The first gate signal GW, which is at the non-active level, may be applied to the gate electrode of the second transistor T2 through the first gate line GWL. Consequently, the second transistor T2 may be turned off.

The emission signal EM, which is at the non-active level, may be applied to the counter gate electrode of the first transistor T1 through the emission line EML. Consequently, the first transistor T1 may be turned off.

As the third transistor T3 is turned on, the reference voltage Vref may be applied to the first node N1 through the turned-on third transistor T3. Therefore, the gate electrode of the first transistor T1, which is connected to the first node N1, may be initialized to the reference voltage Vref.

As the fourth transistor T4 is turned on, the initialization voltage Vaint may be applied to the anode of the light-emitting element ED through the turned-on fourth transistor T4. Consequently, the anode of the light-emitting element ED may be initialized to the initialization voltage Vaint.

As the fifth transistor T5 is turned on, the initialization voltage Vaint may be applied to the second node through the turned-on fifth transistor T5. Consequently, the source electrode of the first transistor T1, which is connected to the second node N2, may be initialized to the initialization voltage Vaint.

Additionally, the difference between the reference voltage Vref at the first node N1 and the initialization voltage Vaint at the second node N2, such as the gate-source voltage of the first transistor T1, may be greater than the threshold voltage of the first transistor T1. However, since the emission signal EM at the non-active level is applied to the counter gate electrode of the first transistor T1, as described above, the first transistor T1 may be turned off. For example, when the emission signal EM which is applied to the counter gate electrode of the first transistor T1 is at the non-active level, the threshold voltage of the first transistor T1 may be shifted to increase, and as a result, the gate-source voltage of the first transistor T1 may become less than the increased threshold voltage of the first transistor T1. Therefore, when the emission signal EM is at the non-active level, the first transistor T1 can always remain turned off regardless of its gate-source voltage. In an embodiment, the emission signal EM at the non-active level may have a voltage that is less than or equal to a gate signal at the non-active level. For example, the voltage of the emission signal EM at the non-active level may be the same as or less than that of the first gate signal GW at the non-active level.

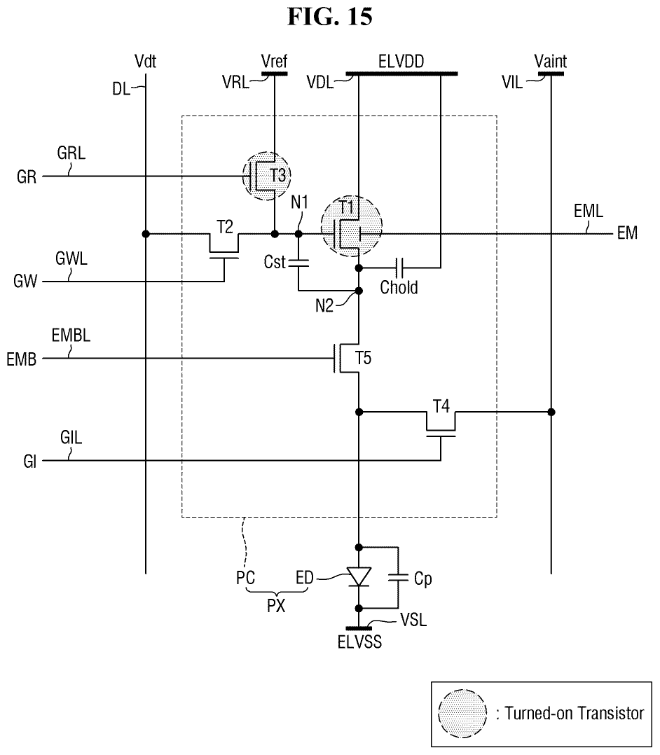

The operation of the display device 10 during the threshold voltage detection period P2 will hereinafter be described with reference to FIGS. 13 and 15, according to an embodiment, where FIG. 15 is a circuit diagram for explaining the operation of the display device 10 of FIG. 12 during the threshold voltage detection period P2 of FIG. 13.

As illustrated in FIG. 13, during the threshold voltage detection period P2, the second gate signal GR and the emission signal EM may each be at the active level. However, during the threshold voltage detection period P2, the first, third, and fourth gate signals GW, GI, and EMB, respectively, may each be at the non-active level.

The second gate signal GR, which is at the active level, may be applied to the gate electrode of the third transistor T3 through the second gate line GRL. Consequently, the third transistor T3 may be turned on.

The emission signal EM, which is at the active level, may be applied to the counter gate electrode of the first transistor T1 through the emission line EML. Consequently, during the threshold voltage detection period P2, the first transistor T1 may be turned on and then turned off as will be described later.

The first gate signal GW, which is at the non-active level, may be applied to the gate electrode of the second transistor T2 through the first gate line GWL. Consequently, the second transistor T2 may be turned off.

The third gate signal GI, which is at the non-active level, may be applied to the gate electrode of the fourth transistor T4 through the third gate line GIL. Consequently, the fourth transistor T4 may be turned off.

The fourth gate signal EMB, which is at the non-active level, may be applied to the gate electrode of the fifth transistor T5 through the fourth gate line EMBL. Consequently, the fifth transistor T5 may be turned off.

The reference voltage Vref may be applied to the first node N1 via the turned-on third transistor T3, and as a result, the voltage of the gate electrode of the first transistor T1 may be maintained at the reference voltage Vref. The voltage of the source electrode of the first transistor T1 is the initialization voltage Vaint, which is applied during the previous period (i.e., the first initialization period P1), and since the emission signal EM, which is applied to the counter gate electrode of the first transistor T1, is at the active level, the first transistor T1 may be turned on during the threshold voltage detection period P2. Additionally, during the threshold voltage detection period P2, the second node N2 remains floating due to the turned-off fourth transistor T4, allowing the voltage of the second node N2 to gradually increase due to the current flowing through the turned-on first transistor T1. In other words, as the fourth transistor T4 is turned off, the supply of the initialization voltage Vaint to the second node N2 is interrupted, causing the voltage of the second node N2 to rise and thereby gradually reducing the current flowing through the first transistor T1. Consequently, the gate-source voltage of the first transistor T1 gradually decreases until the first transistor T1 is turned off when its gate-source voltage reaches the threshold voltage of the first transistor T1. Then, the detected threshold voltage of the first transistor T1 may be reflected in the second node N2. Moreover, the detected threshold voltage of the first transistor T1 may be stored and maintained at the second node N2 by the first capacitor Cst.

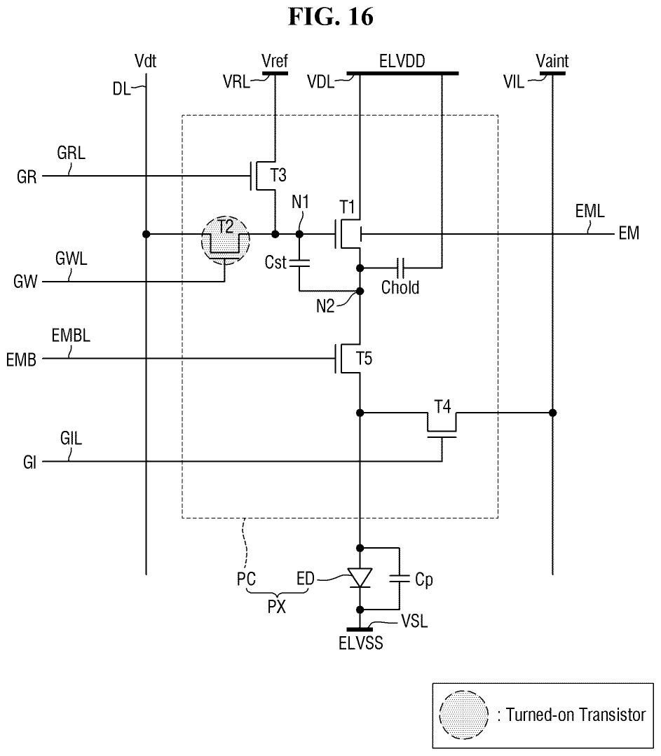

The operation of the display device 10 during the data write period P3 will hereinafter be described with reference to FIGS. 13 and 16, according to an embodiment, where FIG. 16 is a circuit diagram for explaining the operation of the display device 10 of FIG. 12 during the data write period P3 of FIG. 13.

As illustrated in FIG. 13, during the data write period P3, the first gate signal GW may be at the active level. However, during the data write period P3, the second, third, and fourth gate signals GR, GI, and EMB, respectively, and the emission signal EM may each be at the non-active level. Moreover, during the data write period P3, the data voltage Vdt may be applied to the data line DL.

The first gate signal GW, which is at the active level, may be applied to the gate electrode of the second transistor T2 through the first gate line GWL. Consequently, the second transistor T2 may be turned on.

The second gate signal GR, which is at the non-active level, may be applied to the gate electrode of the third transistor T3 through the second gate line GRL. Consequently, the third transistor T3 may be turned off.

The third gate signal GI, which is at the non-active level, may be applied to the gate electrode of the fourth transistor T4 through the third gate line GIL. Consequently, the fourth transistor T4 may be turned off.

The fourth gate signal EMB, which is at the non-active level, may be applied to the gate electrode of the fifth transistor T5 through the fourth gate line EMBL. Consequently, the fifth transistor T5 may be turned off.

The emission signal EM, which is at the non-active level, may be applied to the counter gate electrode of the first transistor T1 through the emission line EML.

As the second transistor T2 is turned on, the data voltage Vdt from the data line DL may be applied to the first node N1 through the turned-on second transistor T2. In other words, the data voltage Vdt from the data line DL may be applied to the gate electrode of the first transistor T1. The magnitude of the data voltage Vdt added to the voltage of the first node N1 may be determined by the ratio of the capacitance of the second capacitor Chold to the combined capacitance of the first capacitor Cst and the second capacitor Chold. For example, the voltage added to the first node N1 may be determined as “data voltage Vdt*(capacitance of the second capacitor Chold/(capacitance of the first capacitor Cst+capacitance of the second capacitor Chold)),” where, the data voltage Vdt may be a voltage with a predetermined grayscale (or brightness) for displaying an image. Moreover, during the data write period P3, the first transistor T1 may remain turned off due to the emission signal EM at the non-active level applied to the counter gate electrode of the first transistor T1.

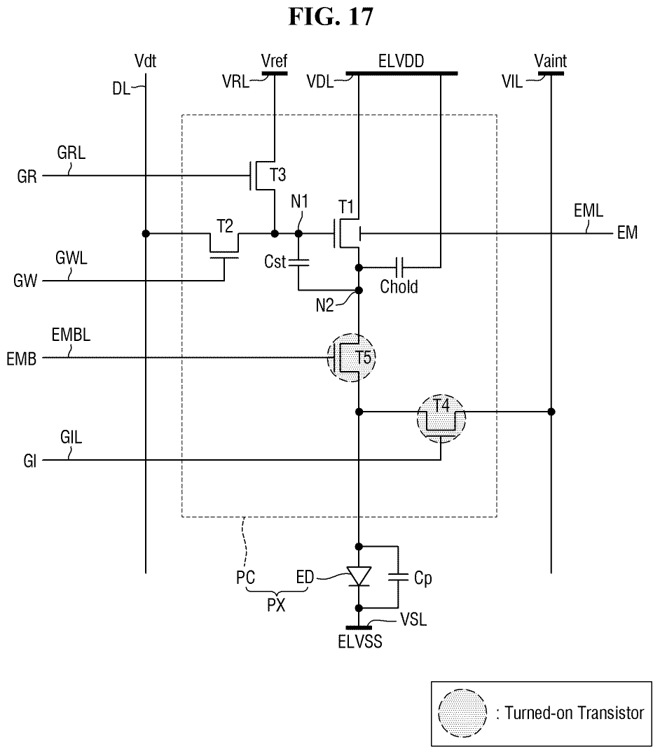

The operation of the display device 10 during the second initialization period P4 will hereinafter be described with reference to FIGS. 13 and 17, according to an embodiment, where FIG. 17 is a circuit diagram for explaining the operation of the display device 10 of FIG. 12 during the second initialization period P4 of FIG. 13.

As illustrated in FIG. 13, during the second initialization period P4, the third and fourth gate signals GI and EMB, respectively, may each be at the active level. However, during the second initialization period P4, the first gate signal GW, the second gate signal GR, and the emission signal EM may each be at the non-active level.

The third gate signal GI, which is at the active level, may be applied to the gate electrode of the fourth transistor T4 through the third gate line GIL. Consequently, the fourth transistor T4 may be turned on.

The fourth gate signal EMB, which is at the active level, may be applied to the gate electrode of the fifth transistor T5 through the fourth gate line EMBL. Consequently, the fifth transistor T5 may be turned on.

The first gate signal GW, which is at the non-active level, may be applied to the gate electrode of the second transistor T2 through the first gate line GWL. Consequently, the second transistor T2 may be turned off.

The second gate signal GR, which is at the non-active level, may be applied to the gate electrode of the third transistor T3 through the second gate line GRL. Consequently, the third transistor T3 may be turned off.

The emission signal EM, which is at the non-active level, may be applied to the counter gate electrode of the first transistor T1 through the emission line EML.

As the fourth transistor T4 is turned on, the initialization voltage Vaint from the initialization voltage line VIL may be applied to the anode of the light-emitting element ED through the turned-on fourth transistor T4. Accordingly, the voltage of the anode of the light-emitting element ED may be initialized to the initialization voltage Vaint.

As the fifth transistor T5 is turned on, the initialization voltage Vaint from the initialization voltage line VIL may be applied to the second node N2 through the turned-on fifth transistor T5. Consequently, the voltage of the second node N2 may be initialized to the initialization voltage Vaint.

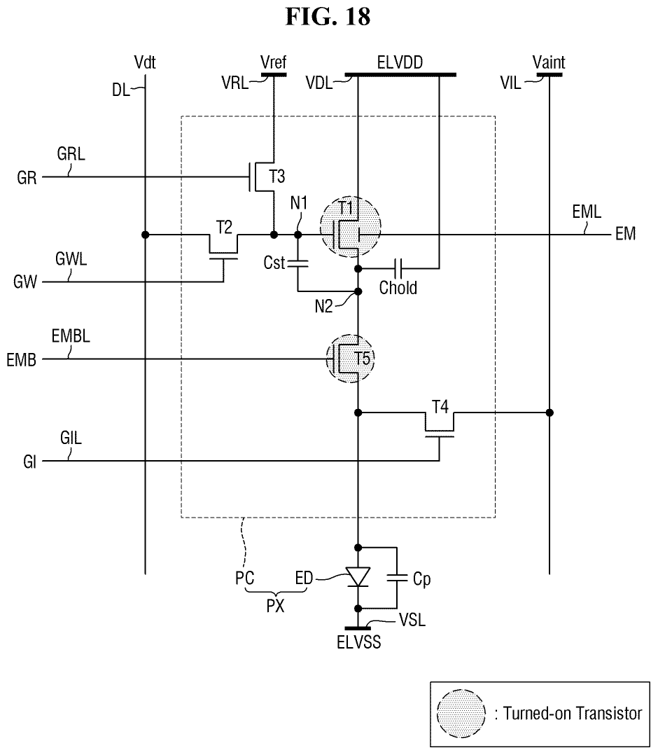

The operation of the display device 10 during the emission period P5 will hereinafter be described with reference to FIGS. 13 and 18, according to an embodiment, where FIG. 18 is a circuit diagram for explaining the operation of the display device 10 of FIG. 12 during the emission period P5 of FIG. 13.

As illustrated in FIG. 13, during the emission period P5, the emission signal EM and the fourth gate signal EMB may each be at the active level. However, during the emission period P5, the first, second, and third gate signals GW, GR, and GI, may each be at the non-active level.

The emission signal EM, which is at the active level, may be applied to the counter gate electrode of the first transistor T1 through the emission line EML.

The fourth gate signal EMB, which is at the active level, may be applied to the gate electrode of the fifth transistor T5 through the fourth gate line EMBL. Consequently, the fifth transistor T5 may be turned on.

The first gate signal GW, which is at the non-active level, may be applied to the gate electrode of the second transistor T2 through the first gate line GWL. Consequently, the second transistor T2 may be turned off.

The second gate signal GR, which is at the non-active level, may be applied to the gate electrode of the third transistor T3 through the second gate line GRL. Consequently, the third transistor T3 may be turned off.

The third gate signal GI, which is at the non-active level may be applied to the gate electrode of the fourth transistor T4 through the third gate line GIL. Consequently, the fourth transistor T4 may be turned off.

During the emission period P5, the first transistor T1 may remain turned on due to the gate-source voltage being maintained by the first capacitor Cst and the emission signal EM being at the active level.

Thus, during the emission period P5, the turned-on first transistor T1 may enable the driving voltage ELVDD to be applied to the first electrode of the light-emitting device ED, i.e., the second node N2, through the turned-on first transistor T1. The magnitude of the driving current flowing into the light-emitting device ED through the turned-on first transistor T1 may be determined based on the data voltage Vdt and the threshold voltage of the first transistor T1. Consequently, the driving current supplied to the light-emitting device ED may accurately reflect the magnitude of the data voltage Vdt. In other words, the driving current may be accurately compensated for the threshold voltage of the first transistor T1. Therefore, by compensating for the threshold voltage of the first transistor T1 of each pixel PX, the driving current of each pixel PX can be determined, minimizing brightness deviations between pixels PX according to the deviations in the threshold voltage of the first transistor T1 between the pixels PX. Accordingly, the display quality of the display device 10 can be enhanced.

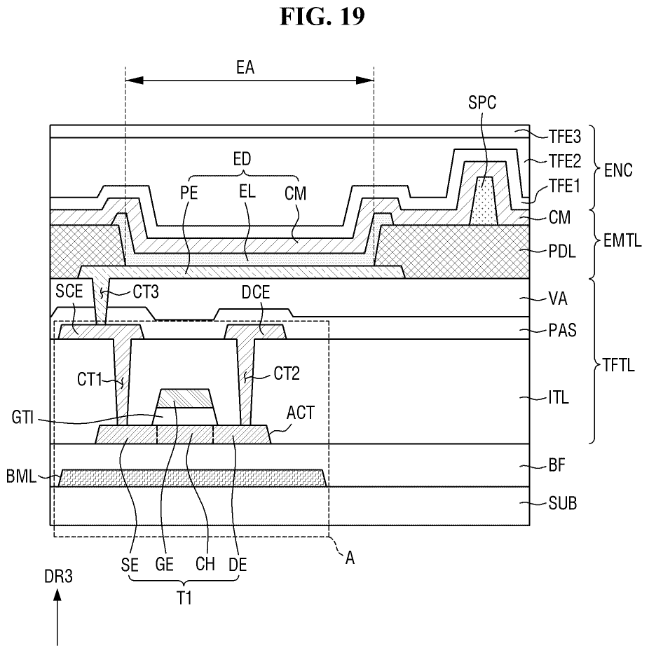

FIG. 19 is a cross-sectional view of a display device 10, according to an embodiment.

In an embodiment and referring to FIG. 19, the display device 10 may include a substrate SUB, a light-shielding layer BML, a buffer film BF, a TFT layer TFTL, a light-emitting element layer EMTL, and an encapsulation layer ENC. The light-shielding layer BML, the buffer film BF, the TFT layer TFTL, the light-emitting element layer EMTL, and the encapsulation layer ENC may be sequentially disposed on the substrate SUB along a third direction DR3. Additionally, the TFT layer TFTL may include the first, second, third, fourth, and fifth transistors T1, T2, T3, T4, and T5, respectively, of FIG. 5 or 13. For simplicity, only the first transistor T1 is illustrated in FIG. 19 as being included in the TFT layer TFTL.

In an embodiment, the substrate SUB may be a rigid substrate or a flexible substrate that is bendable, foldable, or rollable and may be formed of an insulating material such as glass, quartz, or a polymer material. Examples of the polymer material include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), and a combination thereof. In another embodiment, the substrate SUB may include a metal material.

In an embodiment, the light-shielding layer BML may be disposed on the substrate SUB and may be disposed on the substrate SUB to overlap with an active layer ACT. The light-shielding layer BML may be formed of a metal material such as chrome (Cr) or molybdenum (Mo) or a material such as black ink or black dye. The first transistor T1 on the light-shielding layer BML may stabilize electrical characteristics. For example, performance degradation of an oxide-based transistor can be minimized. However, since an oxide semiconductor is sensitive to light, variations in current due to light from an external source may occur. In one embodiment, the light-shielding layer BML may include the counter gate electrode of the first transistor T1. In another embodiment, the light-shielding layer BML may be the counter gate electrode of the first transistor T1. The light-shielding layer BML may receive an emission signal EM.

In an embodiment, the buffer film BF may be disposed on the light-shielding layer BML and may cover the entire surface of the substrate SUB, including the light-shielding layer BML. The buffer film BF may be a film for protecting the first transistor T1 of the TFT layer TFTL and an emission layer EL of the light-emitting element layer from moisture infiltration through the substrate SUB, which is susceptible to humidity. The buffer film BF may include a plurality of inorganic films that are alternately stacked. For example, the buffer film BF may be formed as a multifilm where one or more inorganic films such as a silicon nitride layer, a silicon oxynitride layer, a silicon oxide layer, a titanium oxide layer, and/or an aluminum oxide layer are alternately stacked.

In an embodiment, the active layer ACT may be disposed on the buffer film BF and may include, for example, an oxide semiconductor. For example, the active layer ACT may include indium gallium zinc oxide (IGZO) or indium gallium zinc tin oxide (IGZTO).

In an embodiment, a gate insulating film GTI may be disposed on the active layer ACT. For example, the gate insulating film GTI may be disposed to overlap with a channel area CH of the active layer ACT and may include at least one of tetraethyl orthosilicate (TEOS), silicon nitride (SiNₓ), and silicon oxide (SiO₂). For example, the gate insulating film GTI may have a double-film structure where a silicon nitride film with a thickness of 40 nm and a TEOS film with a thickness of 80 nm are sequentially stacked.

In an embodiment, a gate electrode GE may be disposed on the gate insulating layer GTI and may be disposed on the gate insulating film GTI to overlap with the channel area CH of the active layer ACT. The gate electrode GE may be formed of Al or Ti. Additionally, the gate electrode GE may have a double- or triple-film structure where Al and Ti are stacked.

In an embodiment, the interlayer insulating layer ITL may be disposed on the gate electrode GE and may be disposed on the entire surface of the substrate SUB, including the gate electrode GE. The interlayer insulating film ITL may include an inorganic film such as, for example, a silicon nitride layer, a silicon oxynitride layer, a silicon oxide layer, a titanium oxide layer, or an aluminum oxide layer. Alternatively, the interlayer insulating layer ITL may include a plurality of inorganic films.

In an embodiment, a source connection electrode SCE and a drain connection electrode DCE may be disposed on the interlayer insulating layer ITL. The source connection electrode SCE may be connected to a source electrode SE of the active layer ACT through a first contact hole CT1, which penetrates the interlayer insulating layer ITL. The drain connection electrode DCE may be connected to a drain electrode DE of the active layer ACT through a second contact hole CT2, which penetrates the interlayer insulating layer ITL. The source connection electrode SCE and the drain connection electrode DCE may be formed of the same material as the gate electrode GE.

In an embodiment, a passivation film PAS may be disposed on the source connection electrode SCE and the drain connection electrode DCE, where the passivation film PAS may be disposed on the entire surface of the substrate SUB, including the interlayer insulating layer ITL. The passivation film PAS may be formed of the same material as the interlayer insulating layer ITL.

In an embodiment, a planarization film VA may be disposed on the passivation film PAS to be disposed on the entire surface of the substrate SUB, including the planarization film VA. The planarization film VA may include a film of an organic material such as an acrylic resin, epoxy resin, phenolic resin, polyamide resin, or polyimide resin.

In an embodiment, a light-emitting element layer EMTL, including a pixel electrode PE, may be disposed on the planarization film VA. The pixel electrode PE may be connected to the source connection electrode SCE through a third contact hole CT3, which penetrates the planarization film VA. The pixel electrode PE may be connected to the source electrode SE of the active layer ACT through the source connection electrode SCE.

In an embodiment, the light-emitting element layer EMTL may further include a light-emitting element ED and a bank (or pixel-defining film) PDL.

The light-emitting element ED may include the pixel electrode PE, the emission layer EL, and a common electrode CM. An emission area EA represents an area in the emission layer EL where holes from the pixel electrode PE and electrons from the common electrode CM are combined to emit light. In this case, the pixel electrode PE may be the anode of the light-emitting element ED, and the common electrode CM may be the cathode of the light-emitting element ED.

According to an embodiment, in a top emission structure that emits light toward the common electrode CM relative to the emission layer EL, the pixel electrode PE may be formed as a single layer of Mo, Ti, copper (Cu), or Al or may be formed as a stack of Al and Ti (e.g., Ti/Al/Ti), a stack of Al and indium tin oxide (ITO) (e.g., ITO/AI/ITO), a silver (Ag)-palladium (Pd)-copper (Cu) (APC) alloy, or a stack of an APC alloy and ITO (e.g., ITO/APC/ITO).

In an embodiment, the bank PDL defines the emission area EA of each pixel and may be disposed to expose part of the pixel electrode PE on the planarization film VA. The bank PDL may cover the edges of the pixel electrode PE. The bank PDL may be formed as an organic film of an acrylic resin, an epoxy resin, a phenolic resin, a polyamide resin, or a polyimide resin.

In an embodiment, a spacer SPC may be disposed on the bank PDL and may support a mask during the fabrication of the emission layer EL. The spacer SPC may be formed as an organic film of an acrylic resin, an epoxy resin, a phenolic resin, a polyamide resin, or a polyimide resin.

In an embodiment, the emission layer EL may be formed on the pixel electrode PE and may include an organic material and may emit light of a particular color. For example, the emission layer EL may include a hole transport layer, an organic material layer, and an electron transport layer. The organic material layer may include a host and a dopant. The organic material layer may include a material capable of emitting light of a particular color and may be formed using a phosphorescent or fluorescent material.

In an embodiment, a plurality of pixels may include a first pixel, which emits light of a first color through a first emission area, a second pixel, which emits light of a second color through a second emission area, and a third pixel, which emits light of a third color through a third emission area.

In an embodiment, an organic material layer of a first emission layer of the first emission area, which emits light of the first color, may include a host material containing carbazole biphenyl (CBP) or 1,3-bis(carbazol-9-yl) (mCP) and a dopant material containing at least one of bis(1-phenylisoquinoline) acetylacetonate iridium (PIQIr(acac)), bis(1-phenylquinoline) acetylacetonate iridium (PQIr(acac)), tris(1-phenylquinoline) iridium (PQIr), and octaethylporphyrin platinum (PtOEP). In another embodiment, the organic material layer of the first emission area of the first emission area may include a fluorescent material, containing PBD:Eu(DBM)₃(Phen) or perylene, but the invention is not limited thereto.

In an embodiment, an organic material layer of a second emission layer of the second emission area, which emits light of the second color, may include a host material containing CBP or mCP and a dopant material containing fac-tris(2-phenylpyridine) iridium (Ir(ppy)₃). In another embodiment, the organic material layer of the second emission layer of the second emission area may consist of a fluorescent material such as tris(8-hydroxyquinolino) aluminum (Alq3), but the invention is not limited thereto.

In an embodiment, the organic material layer of the emission layer emitting light of the third color may include a host material containing CBP or mCP and a dopant material containing (4,6-F2ppy)2Irpic or L2BD111, but the invention is not limited thereto.

In an embodiment, the common electrode CM may be disposed on the emission layer EL. For example, the common electrode CM may be disposed on the first, second, and third emission layers and may be disposed to cover the first, second, and third emission layers. The common electrode CM may be a common layer that is disposed in common for the first, second, and third emission layers and a capping layer may be formed on the common electrode CM.

According to an embodiment, in the top emission structure, the common electrode CM may be formed of a transparent conductive oxide (TCO), such as ITO or indium zinc oxide (IZO), a semi-transmissive conductive material such as magnesium (Mg), Ag, or an alloy thereof. When the common electrode CM is formed of a semi-transmissive conductive material, the common electrode CM can enhance light emission efficiency due to microcavities.

In an embodiment, the encapsulation layer ENC may be formed on the light-emitting element layer EMTL and may include at least one inorganic film to prevent oxygen or moisture from penetrating the light-emitting element layer EMTL. Additionally, the encapsulation layer ENC may include at least one organic film to protect the light-emitting element layer EMTL from contaminants such as dust. For example, the encapsulation layer ENC may include a first encapsulation inorganic film TFE1, an encapsulation organic film TFE2, and a second encapsulation inorganic film TFE3.

In an embodiment, the first encapsulation inorganic film TFE1 may be disposed on the common electrode CM, the encapsulation organic film TFE2 may be disposed on the first encapsulation inorganic film TFE1, and the second encapsulation inorganic film TFE3 may be disposed on the encapsulation organic film TFE2. The first and second encapsulation inorganic films TFE1 and TFE3, respectively, may be formed as multilayer films where one or more inorganic films such as a silicon nitride layer, a silicon oxynitride layer, a silicon oxide layer, a titanium oxide layer, and/or an aluminum oxide layer are alternately stacked. The encapsulation organic film TFE2 may be an organic film of an acrylic resin, an epoxy resin, a phenolic resin, a polyamide resin, or a polyimide resin.

Moreover, a barrier film may be further disposed between the substrate SUB and the light-shielding layer BML and may be a protective barrier for the first transistor T1 of the TFT layer TFTL and the emission layer EL of the light-emitting element layer EMTL from moisture penetrating through the substrate SUB, which is susceptible to humidity. In an embodiment, the barrier film may include a plurality of inorganic films that are alternately stacked. For example, the barrier film may be formed as a multilayer film where one or more inorganic films such as a silicon nitride layer, a silicon oxynitride layer, a silicon oxide layer, a titanium oxide layer, and/or an aluminum oxide layer are alternately stacked.

In concluding the detailed description, those skilled in the art will appreciate that many variations and modifications can be made to the preferred embodiments without substantially departing from the principles of the invention. Therefore, the disclosed embodiments of the invention are used in a generic and descriptive sense only and not for purposes of limitation. Each component specifically shown in the embodiments of the invention can be implemented by modification, and such modifications and differences related to application should be construed as being included in the scope of the invention. Moreover, the embodiments or parts of the embodiments may be combined in whole or in part without departing from the scope of the invention.

What is claimed is:

1. A display device comprising:
a pixel circuit; and
a light-emitting element connected between a second node of the pixel circuit and a common voltage line, wherein
the pixel circuit includes a first transistor, connected to a driving voltage line and the second node, wherein
the first transistor includes a gate electrode connected to a first node, and a counter gate electrode connected to an emission line.

2. The display device of claim 1, further comprising:
a second transistor connected to a data line and the first node.

3. The display device of claim 2, further comprising:
a third transistor connected to a reference voltage line and the first node.

4. The display device of claim 3, further comprising:
a fourth transistor connected to the second node and an initialization voltage line.

5. The display device of claim 4, further comprising:
a first capacitor connected to the first node and the second node; and
a second capacitor connected to the second node and the driving voltage line.

6. The display device of claim 5, further comprising:
a first gate line connected to a gate electrode of the second transistor;
a second gate line connected to a gate electrode of the third transistor; and
a third gate line connected to a gate electrode of the fourth transistor.

7. The display device of claim 6, wherein
the data line transmits a data voltage,
the emission line transmits an emission signal,
the first gate line transmits a first gate signal,
the second gate line transmits a second gate signal, and
the third gate line transmits a third gate signal.

8. The display device of claim 7, wherein during a first initialization period, each of the second and third gate signals is at an active level, and each of the first gate signal and the emission signal is at a non-active level.

9. The display device of claim 8, wherein during a threshold voltage detection period that follows the first initialization period, each of the second gate signal and the emission signal is at the active level, and each of the first and third gate signals is at the non-active level.

10. The display device of claim 9, wherein during a data write period that follows the threshold voltage detection period, the first gate signal is at the active level, each of the second gate signal, the third gate signal, the emission signal is at the non-active level, and the data voltage is applied to the data line.

11. The display device of claim 10, wherein during a second initialization period that follows the data write period, the third gate signal is at the active level, and each of the first gate signal, the second gate signal, and the emission signal is at the non-active level.

12. The display device of claim 11, wherein during an emission period that follows the second initialization period, the emission signal is at the active level, and each of the first, second, and third gate signals is at the non-active level.

13. The display device of claim 7, wherein when the emission signal is at the non-active level, the emission signal has a same value as or a smaller value than the first gate signal when the first gate signal is at the non-active level.

14. The display device of claim 5, wherein a capacitance of the second capacitor is greater than a capacitance of the first capacitor.

15. The display device of claim 5, further comprising:
a fifth transistor connected to the second node and an anode of the light-emitting element,
wherein the fourth transistor is connected to the anode of the light-emitting element and the initialization voltage line.

16. The display device of claim 15, further comprising:
a first gate line connected to a gate electrode of the second transistor;
a second gate line connected to a gate electrode of the third transistor;
a third gate line connected to a gate electrode of the fourth transistor; and
a fourth gate line connected to a gate electrode of the fifth transistor.

17. The display device of claim 16, wherein
the data line transmits a data voltage,
the emission line transmits an emission signal,
the first gate line transmits a first gate signal,
the second gate line transmits a second gate signal,
the third gate line transmits a third gate signal, and
the fourth gate line transmits a fourth gate signal.

18. The display device of claim 17, wherein during a first initialization period, each of the second, third, and fourth gate signals is at the active level, and each of the first gate signal and the emission signal is at the non-active level.

19. The display device of claim 18, wherein during a threshold voltage detection period that follows the first initialization period, each of the second gate signal and the emission signal is at the active level, and each of the first, third, and fourth gate signals is at the non-active level.

20. The display device of claim 19, wherein during a data write period that follows the threshold voltage detection period, the first gate signal is at the active level, each of the second gate signal, the third gate signal, the fourth gate signal, and the emission signal is at the non-active level, and the data voltage is applied to the data line.

21. The display device of claim 20, wherein during a second initialization period that follows the data write period, each of the third and fourth gate signals is at the active level, and each of the first gate signal, the second gate signal, and the emission signal is at the non-active level.

22. The display device of claim 21, wherein during an emission period that follows the second initialization period, each of the emission signal and the fourth gate signal is at the active level, and each of the first, second, and third gate signals is at the non-active level.

23. A display device comprising:
a pixel circuit; and
a light-emitting element connected to a second node of the pixel circuit and a common voltage line, wherein
the pixel circuit includes
a first transistor, connected to a driving voltage line and the second node, wherein the first transistor has a gate electrode connected to a first node and a counter gate electrode connected to an emission line,
a second transistor connected to a data line and the first node, wherein the second transistor has a gate electrode connected to a first gate line,
a third transistor connected to a reference voltage line and the first node, wherein the third transistor has a gate electrode connected to a second gate line,
a fourth transistor connected to the second node and an initialization voltage line, wherein the fourth transistor has a gate electrode connected to a third gate line,
a first capacitor connected to the first node and the second node, and a second capacitor connected to the second node and the driving voltage line, wherein
during a first initialization period, each of a second gate signal from the second gate line and a third gate signal from the third gate line is at an active level, and each of a first gate signal from the first gate line and an emission signal from the emission line is at a non-active level,
during a threshold voltage detection period that follows the first initialization period, each of the second gate signal and the emission signal is at the active level, and each of the first and third gate signals is at the non-active level,
during a data write period that follows the threshold voltage detection period, the first gate signal is at the active level, each of the second gate signal, the third gate signal, and the emission signal is at the non-active level, and a data voltage is applied to the data line,
during a second initialization period that follows the data write period, the third gate signal is at the active level, and each of the first gate signal, the second gate signal, and the emission signal is at the non-active level, and
during an emission period that follows the second initialization period, the emission signal is at the active level, and each of the first, second, and third gate signals is at the non-active level.

24. A display device comprising:
a pixel circuit; and
a light-emitting element connected to a second node of the pixel circuit and a common voltage line, wherein
the pixel circuit includes a first transistor connected to a driving voltage line and the second node, wherein the first transistor has a gate electrode connected to a first node and a counter gate electrode connected to an emission line,
a second transistor connected to a data line and the first node, wherein the second transistor has a gate electrode connected to a first gate line,
a third transistor connected to a reference voltage line and the first node, wherein the third transistor has a gate electrode connected to a second gate line,
a fourth transistor connected to an anode of the light-emitting element and an initialization voltage line, wherein the fourth transistor has a gate electrode connected to a third gate line,
a fifth transistor connected to the second node and the anode of the light-emitting element, wherein the fifth transistor has a gate electrode connected to a fourth gate line,
a first capacitor connected to the first node and the second node, and
a second capacitor connected to the second node and the driving voltage line, wherein
during a first initialization period, each of a second gate signal from the second gate line, a third gate signal from the third gate line, and a fourth gate signal from the fourth gate line is at an active level, and each of a first gate signal from the first gate line and an emission signal from the emission line is at a non-active level,
during a threshold voltage detection period that follows the first initialization period, each of the second gate signal and the emission signal is at the active level, and each of the first, third, and fourth gate signals is at the non-active level,
during a data write period that follows the threshold voltage detection period, the first gate signal is at the active level, each of the second gate signal, the third gate signal, the fourth gate signal, and the emission signal is at the non-active level, and a data voltage is applied to the data line,
during a second initialization period that follows the data write period, each of the third gate signal and the fourth gate signal is at the active level, and each of the first gate signal, the second gate signal, and the emission signal is at the non-active level, and
during an emission period that follows the second initialization period, each of the emission signal and the fourth gate signal is at the active level, and each of the first, second, and third gate signals is at the non-active level.
